(19) United States
(12) Patent Application Publication
(10) Pub. No.: US 2025/0374783 A1
(43) Pub. Date: Dec. 4, 2025

(54) DISPLAY DEVICE AND ELECTRONIC DEVICE INCLUDING THE SAME

(71) Applicant: Samsung Display Co., Ltd., Yongin-si (KR)

(72) Inventors: Seung Hwan CHO, Yongin-si (KR); Tae Ho KIM, Yongin-si (KR); Seung Jun LEE, Yongin-si (KR); Yong Su LEE, Yongin-si (KR); Jae Woo LEE, Yongin-si (KR)

(21) Appl. No.: 19/201,400

(22) Filed: May 7, 2025

(30) Foreign Application Priority Data
Jun. 4, 2024 (KR) 10-2024-0073149

(51) Int. Cl. H10K 59/131; G06V 40/13; G09G 3/32; H10K 39/34

(52) U.S. Cl. CPC H10K 59/131; G06V 40/1318; G09G 3/32; H10K 39/34; G09G 2300/0819; G09G 2300/0842; G09G 2300/0861; G09G 2320/0223; G09G 2360/14

(57) ABSTRACT

A display device includes a substrate having a display area including a first area and a second area, and a non-display area, first signal lines including data lines connected to pixels, and readout lines connected to sensor pixels, in the first area and in the second area, second signal lines between the first signal lines in the first area and in the second area, and connection lines in the display area, and connecting at least some of the first signal lines in the first area to corresponding ones of the second signal lines in the second area.

### CROSS-REFERENCE TO RELATED APPLICATION

The present application claims priority to, and the benefit of, Korean Patent Application No. 10-2024-0073149, filed on Jun. 4, 2024, in the Korean Intellectual Property Office, the entire disclosure of which is incorporated herein by reference.

### BACKGROUND

### 1. Field

The present disclosure relates to a display device including an optical sensor, and an electronic device including the same.

### 2. Description of the Related Art

Recently, as interest in information display is increasing, research and development on display devices are continuously made.

### SUMMARY

An aspect of the present disclosure provides a display device with a reduced dead space, and an electronic device.

The aspects of the present disclosure are not limited to those described above, and other aspects not described may become apparent to those of ordinary skill in the art based on the following descriptions.

A display device according to embodiments of the present disclosure includes a substrate having a display area including a first area and a second area, and a non-display area, first signal lines including data lines connected to pixels, and readout lines connected to sensor pixels, in the first area and in the second area, second signal lines between the first signal lines in the first area and in the second area, and connection lines in the display area, and connecting at least some of the first signal lines in the first area to corresponding ones of the second signal lines in the second area.

The first signal lines and the second signal lines may extend in a second direction, and may be arranged along a first direction crossing the second direction, wherein the first area and the second area are separated in the first direction.

The data lines and the readout lines in the first area may be respectively connected to corresponding ones of the connection lines.

The display device may further include third signal lines connected to pads in the non-display area, directly connected to some of the first signal lines in the second area, and connected to others of the first signal lines in the first area through the connection lines.

The display device may further include a driver connected to the first signal lines and the second signal lines through the third signal lines, and alternately connected to the data lines and the readout lines according to an arrangement order of the third signal lines.

The data lines may include a first data line, a second data line, a third data line, a fourth data line, and a fifth data line sequentially located along a first direction in plan view, wherein the second signal lines include a second bridge line and a third bridge line between the second data line and the third data line, and a fourth bridge line and a fifth bridge line between the fourth data line and the fifth data line, wherein the second data line in the first area is connected to the fifth bridge line in the second area through a first connection line, and wherein the third data line in the first area is connected to the fourth bridge line in the second area through a second connection line.

The readout lines may include a first readout line between the first data line and the second data line, and a second readout line between the third data line and the fourth data line, wherein the first readout line in the first area is connected to a sixth bridge line between a sixth data line and a seventh data line in the second area through a third connection line.

The display device may further include dummy lines extending from the second signal lines connected to the connection lines in an extending direction of the second signal lines, and physically separated from the second signal lines.

The dummy lines may be floating, and may be physically separated from the first signal lines.

The dummy lines may be configured to receive a power voltage.

The display device may further include third signal lines in the non-display area, and connecting the first signal lines and the second signal lines with pads, and a shielding layer between one of the third signal lines connected to the readout lines and others of the first, second, and third signal lines, wherein the one of the third signal lines is at a different layer from the others of the first, second, and third signal lines with the shielding layer therebetween.

The display device may further include third signal lines in the non-display area, and connecting the first signal lines and the second signal lines with pads, and shielding lines between ones of the third signal lines connected to the readout lines and others of the first, second, and third signal lines.

At least some of the others of the first, second, and third signal lines and the ones of the third signal lines may be at a same layer, wherein the shielding lines are at a different layer from the ones of the third signal lines.

In the first area, the data lines may be connected to the connection lines, wherein the readout lines in the first area are not connected to the connection lines.

The display device may further include third signal lines in the non-display area and connected to pads, wherein the readout lines in the first area and the first signal lines in the second area are directly connected to the third signal lines, and wherein the data lines in the first area are connected to the third signal lines through the connection lines.

The display device may further include a shielding layer between one of the third signal lines connected to the readout lines and others of the first, second, an third signal lines, wherein the one of the third signal lines is at a different layer from the others of the first, second, and third signal lines with the shielding layer therebetween.

The readout lines in the first area may be connected to the connection lines, wherein the data lines in the first area are not connected to the connection lines.

The display device may further include third signal lines in the non-display area and connected to pads, wherein the data lines in the first area and the first signal lines in the second area are directly connected to the third signal lines, and wherein the readout lines in the first area are connected to the third signal lines through the connection lines.

The pixels may include a light-emitting element, wherein the sensor pixels include a light-receiving element at a same layer as the light-emitting element.

An electronic device according to embodiments of the present disclosure includes a processor configured to provide input image data, a display device configured to display an image based on the input image data, and a power supply device configured to supply power to the display device, wherein the display device includes a substrate having a display area including a first area and a second area, and a non-display area, first signal lines in the first area and in the second area, and including data lines connected to pixels, and readout lines connected to sensor pixels, second signal lines between the first signal lines in the first area and the second area, and connection lines in the display area, and configured to connect at least some of the first signal lines in the first area to corresponding ones of the second signal lines in the second area.

Specific details of other embodiments are included in the detailed description and drawings.

### BRIEF DESCRIPTION OF THE DRAWINGS

FIGS. 1 and 2 are schematic plan views illustrating a display device according to embodiments.

FIG. 3 is a schematic cross-sectional view illustrating a display device according to one or more embodiments.

FIG. 4 is a schematic circuit diagram illustrating a subpixel and a light-sensing pixel included in the display device of FIG. 1.

FIG. 5 is a schematic cross-sectional view illustrating one area of the display device of FIG. 1.

FIG. 6 is a schematic cross-sectional view illustrating a reflection path of light in the display device of FIG. 5.

FIG. 7 is a schematic plan view illustrating one area of the display device of FIG. 1.

FIG. 8 is a schematic cross-sectional view taken along an eleventh connection line of FIG. 7 which illustrates one or more embodiments of a display device.

FIG. 9 is a schematic cross-sectional view taken along a second connection line of FIG. 7 which illustrates one or more embodiments of a display device.

FIGS. 10 and 11 are cross-sectional views taken along the line I-I′ of FIG. 7 which illustrates one or more embodiments of a display device.

FIG. 12 is a schematic plan view illustrating one area of the display device of FIG. 1.

FIG. 13 is a cross-sectional view taken along the line II-II′ of FIG. 12 which illustrates one or more embodiments of a display device.

FIG. 14 is a schematic plan view illustrating a display device according to embodiments.

FIG. 15 is a schematic plan view illustrating one area of the display device of FIG. 14.

FIG. 16 is a schematic plan view illustrating one area of the display device of FIG. 14.

FIG. 17 is a cross-sectional view taken along a 1a interconnect of FIG. 16 which illustrates one or more embodiments of a display device.

FIG. 18 is a schematic plan view illustrating one area of the display device of FIG. 14.

FIG. 19 is a block diagram illustrating an electronic device according to embodiments.

### DETAILED DESCRIPTION

Aspects of some embodiments of the present disclosure and methods of accomplishing the same may be understood more readily by reference to the detailed description of embodiments and the accompanying drawings. The described embodiments are provided as examples so that this disclosure will be thorough and complete, and will fully convey the aspects of the present disclosure to those skilled in the art. Accordingly, processes, elements, and techniques that are redundant, that are unrelated or irrelevant to the description of the embodiments, or that are not necessary to those having ordinary skill in the art for a complete understanding of the aspects of the present disclosure may be omitted. Unless otherwise noted, like reference numerals, characters, or combinations thereof denote like elements throughout the attached drawings and the written description, and thus, repeated descriptions thereof may be omitted.

The described embodiments may have various modifications and may be embodied in different forms, and should not be construed as being limited to only the illustrated embodiments herein. The use of “can,” “may,” or “may not” in describing one or more embodiments corresponds to one or more embodiments of the present disclosure.

A person of ordinary skill in the art would appreciate, in view of the present disclosure in its entirety, that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

In the drawings, the relative sizes of elements, layers, and regions may be exaggerated for clarity and/or descriptive purposes. In other words, because the sizes and thicknesses of elements in the drawings are arbitrarily illustrated for convenience of description, the disclosure is not limited thereto. Additionally, the use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

Various embodiments are described herein with reference to sectional illustrations that are schematic illustrations of embodiments and/or intermediate structures. As such, variations from the shapes of the illustrations as a result of, for example, manufacturing techniques and/or tolerances, are to be expected. Further, specific structural or functional descriptions disclosed herein are merely illustrative for the purpose of describing embodiments according to the concept of the present disclosure. Thus, embodiments disclosed herein should not be construed as limited to the illustrated shapes of elements, layers, or regions, but are to include deviations in shapes that result from, for instance, manufacturing.

For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place.

Spatially relative terms, such as “beneath,” “below,” “lower,” “lower side,” “under,” “above,” “upper,” “over,” “higher,” “upper side,” “side” (e.g., as in “sidewall”), and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below,” “beneath,”“or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. Similarly, when a first part is described as being arranged “on” a second part, this indicates that the first part is arranged at an upper side or a lower side of the second part without the limitation to the upper side thereof on the basis of the gravity direction.

Further, the phrase “in a plan view” means when an object portion is viewed from above, and the phrase “in a schematic cross-sectional view” means when a schematic cross-section taken by vertically cutting an object portion is viewed from the side. The terms “overlap” or “overlapped” mean that a first object may be above or below or to a side of a second object, and vice versa. Additionally, the term “overlap” may include stack, face or facing, extending over, covering, or partly covering or any other suitable term as would be appreciated and understood by those of ordinary skill in the art. The expression “not overlap” may include meaning, such as “apart from” or “set aside from” or “offset from” and any other suitable equivalents as would be appreciated and understood by those of ordinary skill in the art. The terms “face” and “facing” may mean that a first object may directly or indirectly oppose a second object. In a case in which a third object intervenes between a first and second object, the first and second objects may be understood as being indirectly opposed to one another, although still facing each other.

It will be understood that when an element, layer, region, or component is referred to as being “formed on,” “on,” “connected to,” or “(operatively or communicatively) coupled to” another element, layer, region, or component, it can be directly formed on, on, connected to, or coupled to the other element, layer, region, or component, or indirectly formed on, on, connected to, or coupled to the other element, layer, region, or component such that one or more intervening elements, layers, regions, or components may be present. In addition, this may collectively mean a direct or indirect coupling or connection and an integral or non-integral coupling or connection. For example, when a layer, region, or component is referred to as being “electrically connected” or “electrically coupled” to another layer, region, or component, it can be directly electrically connected or coupled to the other layer, region, and/or component or one or more intervening layers, regions, or components may be present. The one or more intervening components may include a switch, a resistor, a capacitor, and/or the like. In describing embodiments, an expression of connection indicates electrical connection unless explicitly described to be direct connection, and “directly connected/directly coupled,” or “directly on,” refers to one component directly connecting or coupling another component, or being on another component, without an intermediate component.

In addition, in the present specification, when a portion of a layer, a film, an area, a plate, or the like is formed on another portion, a forming direction is not limited to an upper direction but includes forming the portion on a side surface or in a lower direction. On the contrary, when a portion of a layer, a film, an area, a plate, or the like is formed “under” another portion, this includes not only a case where the portion is “directly beneath” another portion but also a case where there is further another portion between the portion and another portion. Meanwhile, other expressions describing relationships between components, such as “between,” “immediately between” or “adjacent to” and “directly adjacent to,” may be construed similarly. It will be understood that when an element or layer is referred to as being “between” two elements or layers, it can be the only element or layer between the two elements or layers, or one or more intervening elements or layers may also be present.

For the purposes of this disclosure, expressions such as “at least one of,” or “any one of,” or “one or more of” when preceding a list of elements, modify the entire list of elements and do not modify the individual elements of the list. For example, “at least one of X, Y, and Z,” “at least one of X, Y, or Z,” “at least one selected from the group consisting of X, Y, and Z,” and “at least one selected from the group consisting of X, Y, or Z” may be construed as X only, Y only, Z only, any combination of two or more of X, Y, and Z, such as, for instance, XYZ, XYY, YZ, and ZZ, or any variation thereof. Similarly, the expressions “at least one of A and B” and “at least one of A or B” may include A, B, or A and B. As used herein, “or” generally means “and/or,” and the term “and/or” includes any and all combinations of one or more of the associated listed items. For example, the expression “A and/or B” may include A, B, or A and B. Similarly, expressions such as “at least one of,” “a plurality of,” “one of,” and other prepositional phrases, when preceding a list of elements, modify the entire list of elements and do not modify the individual elements of the list. When “C to D” is stated, it means C or more and D or less, unless otherwise specified.

It will be understood that, although the terms “first,” “second,” “third,” etc., may be used herein to describe various elements, components, regions, layers and/or sections, these elements, components, regions, layers and/or sections should not be limited by these terms. These terms do not correspond to a particular order, position, or superiority, and are used only used to distinguish one element, member, component, region, area, layer, section, or portion from another element, member, component, region, area, layer, section, or portion. Thus, a first element, component, region, layer or section described below could be termed a second element, component, region, layer or section, without departing from the spirit and scope of the present disclosure. The description of an element as a “first” element may not require or imply the presence of a second element or other elements. The terms “first,” “second,” etc. may also be used herein to differentiate different categories or sets of elements. For conciseness, the terms “first,” “second,” etc. may represent “first-category (or first-set),” “second-category (or second-set),” etc., respectively.

In the examples, the x-axis, the y-axis, and/or the z-axis are not limited to three axes of a rectangular coordinate system, and may be interpreted in a broader sense. For example, the x-axis, the y-axis, and the z-axis may be perpendicular to one another, or may represent different directions that are not perpendicular to one another. The same applies for first, second, and/or third directions.

The terminology used herein is for the purpose of describing embodiments only and is not intended to be limiting of the present disclosure. As used herein, the singular forms “a” and “an” are intended to include the plural forms as well, while the plural forms are also intended to include the singular forms, unless the context clearly indicates otherwise. It will be further understood that the terms “comprises,” “comprising,” “have,” “having,” “includes,” and “including,” when used in this specification, specify the presence of the stated features, integers, steps, operations, elements, and/or components, but do not preclude the presence or addition of one or more other features, integers, steps, operations, elements, components, and/or groups thereof.

As used herein, the terms “substantially,” “about,” “approximately,” and similar terms are used as terms of approximation and not as terms of degree, and are intended to account for the inherent deviations in measured or calculated values that would be recognized by those of ordinary skill in the art. For example, “substantially” may include a range of +/−5% of a corresponding value. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value. Further, the use of “may” when describing embodiments of the present disclosure refers to “one or more embodiments of the present disclosure.”

In some embodiments well-known structures and devices may be described in the accompanying drawings in relation to one or more functional blocks (e.g., block diagrams), units, and/or modules to avoid unnecessarily obscuring various embodiments. Those skilled in the art will understand that such block, unit, and/or module are/is physically implemented by a logic circuit, an individual component, a microprocessor, a hard wire circuit, a memory element, a line connection, and other electronic circuits. This may be formed using a semiconductor-based manufacturing technique or other manufacturing techniques. The block, unit, and/or module implemented by a microprocessor or other similar hardware may be programmed and controlled using software to perform various functions discussed herein, optionally may be driven by firmware and/or software. In addition, each block, unit, and/or module may be implemented by dedicated hardware, or a combination of dedicated hardware that performs some functions and a processor (for example, one or more programmed microprocessors and related circuits) that performs a function different from those of the dedicated hardware. In addition, in some embodiments, the block, unit, and/or module may be physically separated into two or more interact individual blocks, units, and/or modules without departing from the scope of the present disclosure. In addition, in some embodiments, the block, unit and/or module may be physically combined into more complex blocks, units, and/or modules without departing from the scope of the present disclosure.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

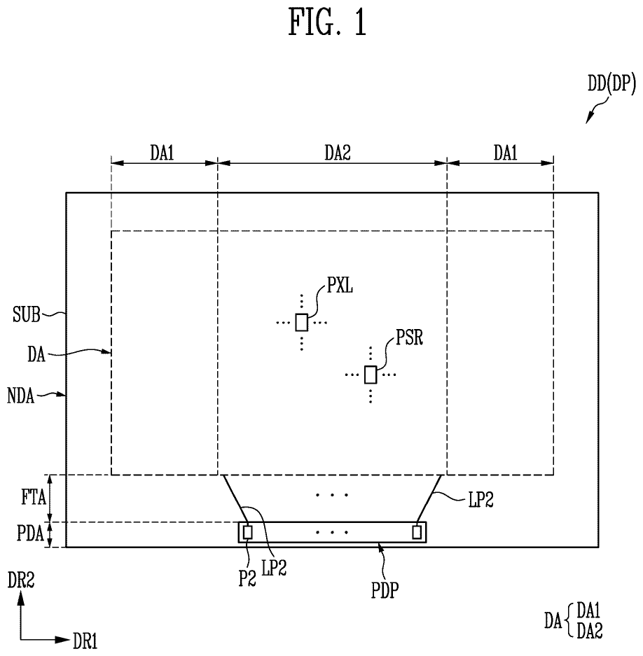

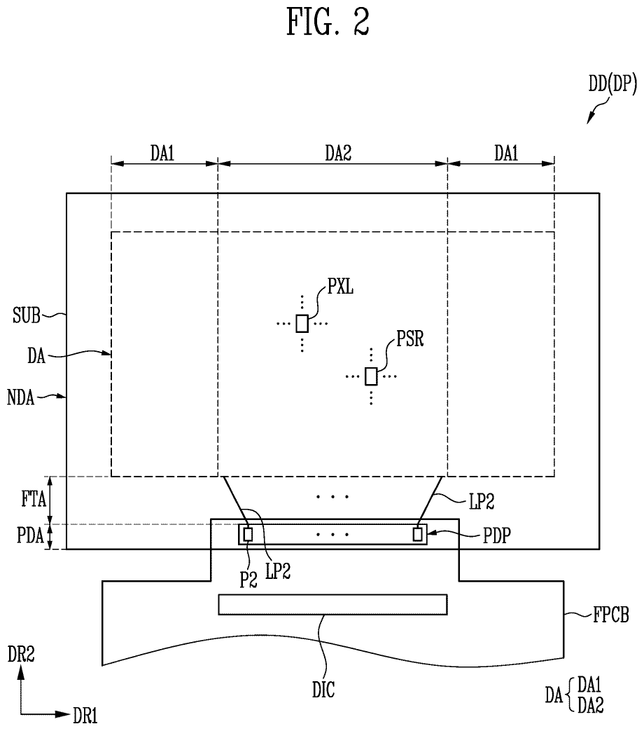

FIGS. 1 and 2 are schematic plan views illustrating a display device according to embodiments.

In FIGS. 1 and 2, for convenience of description, a structure of a display device DD, for example, a structure of a display panel DP provided in the display device DD, is briefly shown generally centered on a display area DA in which an image is displayed.

Referring to FIGS. 1 and 2, the display device DD (or the display panel DP) may include a substrate SUB, subpixels PXL (or pixels), and/or light-sensing pixels PSR (or optical sensors, optical sensor pixels, or sensor pixels).

The display device DD may be provided in various shapes. As an example, the display device DD may be provided in a rectangular plate shape with two pairs of sides that are parallel to each other, but the present disclosure is not limited thereto. The display device DD may be applied to any electronic device, such as a smartphone, a television, a tablet personnel computer (PC), a mobile phone, a video phone, an e-book reader, a desktop PC, a laptop PC, a netbook computer, a workstation, a server, a personal digital assistant (PDA), a portable multimedia player (PMP), an MP 3 player, a medical device, a camera, or a wearable device of which at least one surface is applied as a display surface.

The substrate SUB may include a transparent insulating material to transmit light. The substrate SUB may be a rigid substrate or a flexible substrate. The rigid substrate may be one of a glass substrate, a quartz substrate, a glass ceramic substrate, or a crystalline glass substrate. The flexible substrate may be one of a film substrate including a polymer organic material and a plastic substrate. For example, the flexible substrate may include at least one selected from polystyrene, polyvinyl alcohol, polymethyl methacrylate, polyethersulfone, polyacrylate, polyetherimide, polyethylene naphthalate, polyethylene terephthalate, polyphenylene sulfide, polyarylate, polyimide, polycarbonate, triacetate cellulose, and cellulose acetate propionate, but the present disclosure is necessarily limited thereto.

One area of the substrate SUB may be provided as the display area DA in which the subpixels PXL and the light-sensing pixels PSR are located, and the remaining area of the substrate SUB may be provided as a non-display area NDA.

In one or more embodiments, the display area DA may include a first area(s) DA1 and a second area DA2. The first area DA1 and the second area DA2 may be separated in a first direction DR1. The first area DA1 may be positioned at each of both sides of the second area DA2. For example, the second area DA2 may be positioned at a central portion of the substrate SUB (or the display device DD), and the first area DA1 may be positioned at an edge of the substrate SUB. The second area DA2 may be positioned at an inner side, and the first area DA1 may be positioned at an outer side, but the present disclosure is not necessarily limited thereto. For example, the first area DA1 may be positioned at one side (for example, a right side) of the display area DA, and/or may be positioned at the other side (for example, a left side) of the display area DA.

The second area DA2 may be one area of the display area DA corresponding to a second interconnect LP2 (or a second wiring), and the first area DA1 may be the remaining area of the display area DA excluding the second area DA2.

The second area DA2 may be adjacent to one area of the non-display area NDA in which the second interconnect LP2 is positioned, and the first area DA1 may be adjacent to another area of the non-display area NDA.

The subpixels PXL and the light-sensing pixels PSR may be located in the first area DA1 and the second area DA2. The subpixels PXL may include light-emitting elements each including an light-emitting layer. According to embodiments, the light-emitting element may include an organic light-emitting diode or an inorganic light-emitting diode having a size ranging from micrometers to nanometers, but the present disclosure is not limited thereto. The display device DD may display an image in the first area DA1 and the second area DA2 by driving the subpixels PXL in response to input image data.

The display area DA may include a sensing area capable of detecting a user's fingerprint or the like. For example, the first area DA1 and the second area DA2 may be set as sensing areas capable of detecting a user's fingerprint or the like. When the entire display area DA is set as a sensing area, the non-display area NDA surrounding the display area DA may become a non-sensing area.

The light-sensing pixels PSR may be located in the first area DA1 and the second area DA2. The light-sensing pixels PSR may each include a light-receiving element including a light-receiving layer. In the first area DA1 and the second area DA2, the light-receiving layer of the light-receiving element may be spaced apart from the light-emitting layer of the light-emitting element.

The light-sensing pixels PSR may detect that light emitted from a light source (for example, the light-emitting element) that is reflected by an external object (for example, a user's finger or the like). As an example, a user's fingerprint may be detected through the light-sensing pixels PSR. Hereinafter, an example in which the light-sensing pixels PSR are used for detecting a fingerprint will be described, but in various embodiments, the light-sensing pixels PSR may detect various pieces of biometric information of an iris, a veins, and the like. In addition, the light-sensing pixels PSR may detect external light, and may also perform functions of a gesture sensor, a motion sensor, a proximity sensor, an illumination sensor, and/or an image sensor.

In addition, first signal lines connected to the subpixels PXL and the light-sensing pixels PSR may be located in the first area DA1 and the second area DA2. For example, data lines connected to the subpixels PXL and readout lines connected to the light-sensing pixels PSR may be located in the first area DA1 and the second area DA2.

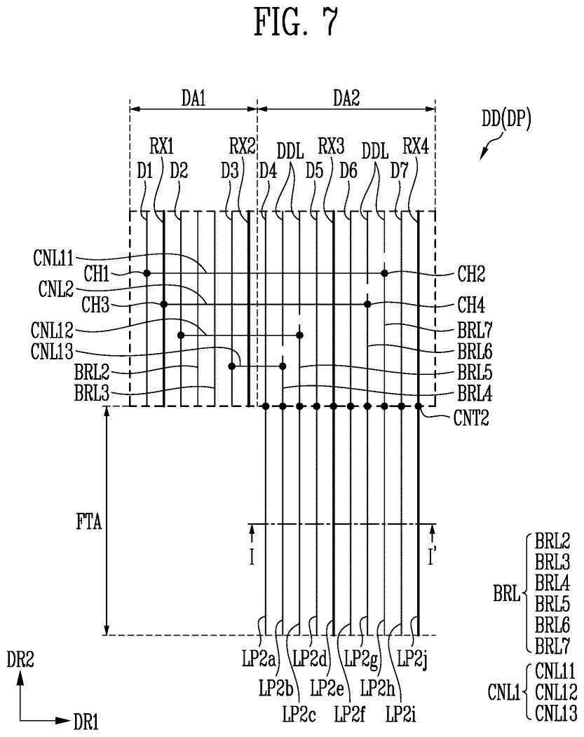

In one or more embodiments, second signal lines (or bridge lines) may be located between the first signal lines in the first area DA1 and the second area DA2, and connection lines, which extend from the first area DA1 to the second area DA2, and which connect at least some of the first signal lines of the first area DA1 to the second signal lines of the second area DA2, may be located. The second signal lines and the connection lines will be described below with reference to FIG. 7.

An interconnect portion, a pad portion PDP, and/or an internal circuit unit for driving the subpixels PXL and the light-sensing pixels PSR may be located in the non-display area NDA. The non-display area NDA may include a fan-out area FTA and a pad area PDA.

The pad area PDA may be an area of the non-display area NDA in which the pad portion PDP is positioned, and may be positioned at an edge of the non-display area NDA.

The fan-out area FTA may be an area of the non-display area NDA in which the interconnect portion LP is positioned and may be positioned between the display area DA and the pad area PDA in the non-display area NDA.

The interconnect portion may be positioned in the fan-out area FTA, and the pad portion PDP may be positioned in the pad area PDA. The interconnect portion may be electrically connected to signal lines (for example, data lines connected to the subpixels PXL and to readout lines connected to the light-sensing pixels PSR) of the display area DA. The interconnect portion may transmit a certain signal applied from a driver DIC to the signal lines in the display area DA. The interconnect portion LP may include fan-out lines electrically connecting the driver DIC and the subpixels PXL and electrically connecting the driver DIC and the light-sensing pixels PSR.

The interconnect portion may include the second interconnect LP2 (or third signal lines). For example, the second interconnect LP2 may be positioned at a central portion of the fan-out area FTA to correspond to the second area DA2. The second interconnect LP2 may be located in one area of the fan-out area FTA positioned between the second area DA2 and the pad portion PDP. A plurality of second interconnects LP2 may be provided and may include fan-out lines electrically connected to signal lines positioned in the second area DA2. As an example, the second interconnects LP2 may include fan-out lines electrically connected to the data lines connected to the subpixels PXL to transmit an electrical signal (for example, a data signal) from the driver DIC to the subpixels PXL. As an example, the second interconnects LP2 may include fan-out lines electrically connected to the readout lines connected to the light-sensing pixels PSR to transmit an electrical signal (for example, a detection signal) received from the light-sensing pixels PSR to the driver DIC.

In one or more embodiments, the second interconnects LP2 may include fan-out lines electrically connected to signal lines positioned in the first area DA1 (for example, the data lines connected to the subpixels PXL and the readout lines connected to the light-sensing pixels PSR) through connection lines extending from the first area DA1 to the second area DA2.

Because the signal lines positioned in the first area DA1 are connected to the second interconnects LP2 through the connection lines, interconnects (or first interconnects) may be omitted in one area of the fan-out area FTA positioned between the first area DA1 and the pad portion PDP. Therefore, as compared to a case in which the first interconnect is located in one area of the fan-out area FTA positioned between the first area DA1 and the pad portion PDP, an area of the fan-out area FTA (for example, a width in a second direction DR2) may be reduced. As another example, as compared to a case in which only the subpixels PXL are located in the display area DA, when the light-sensing pixels PSR are additionally located in the display area DA, the area of the fan-out area FTA may be increased. However, according to embodiments, the signal lines positioned in the first area DA1 may be connected to the second interconnects LP2 through the connection lines, and thus the area of the fan-out area FTA may not be increased or may be reduced.

The pad portion PDP may be located in the pad area PDA, and may supply driving power and signals for driving the subpixels PXL and the light-sensing pixels PSR located in the display area DA. The pad portion PDP may be electrically connected to the interconnect portion. In one or more embodiments, the pad portion PDP may include a second pad P2 electrically connected to the second interconnect LP2.

A plurality of second pads P2 may be provided. The second pad P2 may be electrically connected to the signal lines (for example, data lines and readout lines) positioned in the second area DA2 through the corresponding second interconnects LP2. In addition, the second pad P2 may be electrically connected to the connection line through the corresponding second interconnect LP2.

The display device DD may include a circuit board FPCB connected to the display panel DP through the pad portion PDP. The circuit board FPCB may be a flexible circuit board, but is not limited thereto. The circuit board FPCB may process various signals input from a printed circuit board to output the processed signals to the display panel DP. One end of the circuit board FPCB may be attached to the display panel DP, and the other end of the circuit board FPCB may be attached to the printed circuit board. The circuit board FPCB may be connected to each of the display panel DP and to the printed circuit board through a conductive adhesive member (for example, an anisotropic conductive film).

The driver DIC may be mounted on the circuit board FPCB. For example, the driver DIC may be an integrated circuit (IC). The driver DIC may include a panel driver and a fingerprint detector.

The panel driver may sequentially scan the subpixels PXL to supply a data signal corresponding to an image data signal to the subpixels PXL. The display panel DP may display an image corresponding to an image data signal. The panel driver may supply a driving signal for detecting a fingerprint to the subpixels PXL. The driving signal may be provided to cause the subpixels PXL to emit light and to operate as light sources for the light-sensing pixels PSR. In one or more embodiments, the panel driver may also supply driving signals for sensing a fingerprint and/or other driving signals to the light-sensing pixels PSR. However, the present disclosure is not limited thereto, and the driving signals for sensing a fingerprint may be provided by the fingerprint detector.

The fingerprint detector may detect biometric information about a user's fingerprint or the like based on a detection signal received from the light-sensing pixels PSR. The fingerprint detector may supply driving signals to the light-sensing pixels PSR and/or the subpixels PXL.

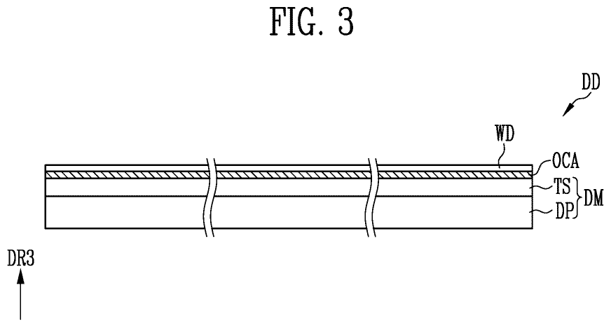

FIG. 3 is a schematic cross-sectional view illustrating a display device according to one or more embodiments.

Referring to FIG. 3, a display device DD may include a display module DM and a window WD.

The display module DM may include a display panel DP and a touch sensor TS. The touch sensor TS may be located directly on the display panel DP or may be located on the display panel DP with a separate layer, such as an adhesive layer or a substrate (or an insulating layer) interposed therebetween.

The display panel DP may display an image. A self-luminescent display panel, such as an organic light-emitting diode (OLED) display panel may be used as the display panel DP. A non-luminescent display panel, such as a liquid crystal display panel (LCD panel), an electrophoretic display panel (EPD panel), or an electrowetting display panel (EWD panel) may be used as the display panel DP. When the non-luminescent display panel is used as the display panel DP, the display device DD may include a backlight unit for supplying light to the display panel DP.

The touch sensor TS is located on a surface of the display panel DP from which an image is emitted, and may receive a user's touch input. The touch sensor TS may recognize a touch event from the display device DD through a user's hand or a separate input means. The touch sensor TS may recognize a touch event using a capacitive method. The touch sensor TS may detect a touch input using a mutual capacitance method or a self-capacitance method.

The window WD (or a cover glass) may be provided on the display module DM to protect an exposed surface of the display module DM. The window WD may protect the display module DM from external shock, and may provide an input surface and/or a display surface to a user. The window WD may be coupled to the display module DM using an optically transparent adhesive OCA. The window WD may have a multilayer structure selected from a glass substrate, a plastic film, and a plastic substrate. The multilayer structure may be formed through a continuous process or an adhesion process using an adhesive layer. The window WD may be fully or partially flexible.

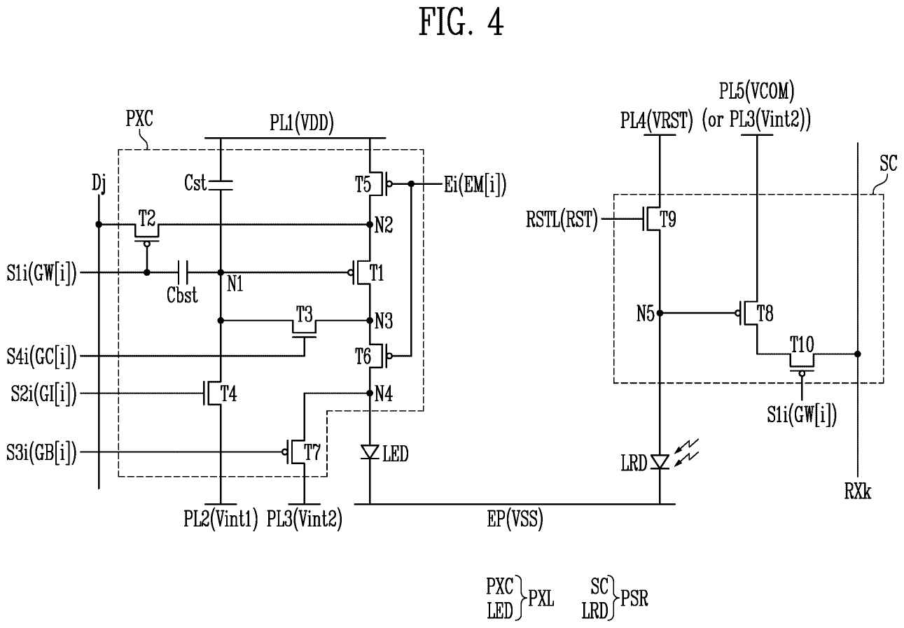

FIG. 4 is a schematic circuit diagram illustrating a subpixel and a light-sensing pixel included in the display device of FIG. 1. For convenience of description, FIG. 4 illustrates a subpixel PXL positioned on an i^{th} horizontal line (or an i^{th} pixel row) and connected to a j^{th} data line Dj.

Referring to FIG. 4, the subpixel PXL and a light-sensing pixel PSR may be located on the i^{th} horizontal line.

The subpixel PXL may include a light-emitting element LED and a pixel circuit PXC. In one or more embodiments, the pixel circuit PXC may include first to seventh transistors T1, T2, T3, T4, T5, T6, and T7, a storage capacitor Cst, and/or a boost capacitor Cbst.

The first transistor T1 (or a driving transistor) may be electrically connected between a first power line PL1 and a first electrode of the light-emitting element LED. The first transistor T1 may include a gate electrode electrically connected to a first node N1. The first transistor T1 may control an amount of a current flowing from the first power line PL1 to an electrode EP (or a power line) through the light-emitting element LED based on a voltage of the first node N1. A first power voltage VDD may be provided to the first power line PL1, a second power voltage VSS may be provided to the electrode EP, and the first power voltage VDD may be set to a higher voltage than the second power voltage VSS.

The second transistor T2 may be electrically connected between the j^{th} data line Dj and a second node N2. A gate electrode of the second transistor T2 may be connected to a 1i scan line (or a first scan line). When a first scan signal GW[i] (for example, a low level first scan signal) is supplied to a 1i scan line S1i, the second transistor T2 may be turned on to electrically connect the j^{th} data line Dj and the second node N2. When each of the first transistor T1 and the third transistor T3 is turned on, the second transistor T2 may transmit a data signal of the j^{th} data line Dj to the first node N1 in response to the first scan signal GW[i].

The third transistor T3 may be electrically connected between the first node N1 and a third node N3. A gate electrode of the third transistor T3 may be electrically connected to a 4i scan line S4i (or a third scan line). The third transistor T3 may be turned on when a fourth scan signal GC[i] is supplied to the 4i scan line S4i. When the third transistor T3 is turned on, the first transistor T1 may be diode-connected.

The fourth transistor T4 may be electrically connected between the first node N1 and a second power line PL2. A gate electrode of the fourth transistor T4 may be electrically connected to a 2i scan line S2i (or a second scan line). A first initialization power voltage Vint1 may be provided to the second power line PL2. The fourth transistor T4 may be turned on by a second scan signal GI[i] supplied to the 2i scan line S2i. When the fourth transistor T4 is turned on, the first initialization power voltage Vint1 may be supplied to the first node N1 (that is, a gate electrode of the first transistor T1).

The fifth transistor T5 may be electrically connected between the first power line PL1 and the second node N2. A gate electrode of the fifth transistor T5 may be electrically connected to an i^{th} emission control line Ei. The sixth transistor T6 may be electrically connected between the third node N3 and the light-emitting element LED (or a fourth node N4). A gate electrode of the sixth transistor T6 may be electrically connected to the i^{th} emission control line Ei. The fifth transistor T5 and the sixth transistor T6 may be turned off when an emission control signal EM[i] (for example, a high level emission control signal EM[i]) is supplied to the i^{th} emission control line Ei and may be turned on in other cases.

The seventh transistor T7 may be electrically connected between the first electrode (for example, the fourth node N4) of the light-emitting element LED and a third power line PL3. A gate electrode of the seventh transistor T7 may be electrically connected to a 3i scan line S3i. A second initialization power voltage Vint2 may be provided to the third power line PL3. According to embodiments, the second initialization power voltage Vint2 may be different from the first initialization power voltage Vint1. The seventh transistor T7 may be turned on by a third scan signal GB [i] supplied to the 3i scan line S3i to supply the second initialization power voltage Vint2 to the first electrode of the light-emitting element LED.

The storage capacitor Cst may be connected or formed between the first power line PL1 and the first node N1.

The boost capacitor Cbst (or a capacitor) may be connected or formed between the gate electrode of the second transistor T2 and the gate electrode of the first transistor T1.

The light-sensing pixel PSR may include a sensor circuit SC and a light-receiving element LRD. The sensor circuit SC may include eighth to tenth transistors T8, T9, and T10.

The eighth transistor T8 and the tenth transistor T10 may be connected in series between a fifth power line PL5 and a k^{th} readout line RXk, wherein k is a positive integer.

The eighth transistor T8 (or a first sensor transistor) may be electrically connected between the fifth power line PL5 and the tenth transistor T10. A gate electrode of the eighth transistor T8 may be electrically connected to a fifth node N5 (or a sensor node). The eighth transistor T8 may control a current flowing from the fifth power line PL5 to the k^{th} readout line RXk through the tenth transistor T10 in response to a voltage of the fifth node N5. A common voltage VCOM may be provided to the fifth power line PL5.

In one or more embodiments, the fifth power line PL5 may be electrically connected to or integrally formed with the third power line PL3. The common voltage VCOM applied to the fifth power line PL5 may be the same as the second initialization power voltage Vint2, but is not limited thereto. According to embodiments, the fifth power line PL5 may be electrically connected to or formed integrally with the second power line PL2. The common voltage VCOM applied to the fifth power line PL5 may be the same as the first initialization power voltage Vint1, but is not limited thereto.

The tenth transistor T10 (a second sensor transistor or a switching transistor) may be electrically connected between the eighth transistor T8 and the k^{th} readout line RXk. A gate electrode of the tenth transistor T10 may be electrically connected to the 1i scan line S1i. The gate electrode of the tenth transistor T10 and the gate electrode of the second transistor T2 may share the 1i scan line S1i.

The ninth transistor T9 (or a third sensor transistor) may be electrically connected between a fourth power line PL4 (or a reference power line) and the fifth node N5. A gate electrode of the ninth transistor T9 may be electrically connected to a reset control line RSTL. A reset voltage VRST may be provided to the fourth power line PL4. The reset voltage VRST may be a DC voltage having a constant level.

At least one light-receiving element LRD may be electrically connected between the fifth node N5 and the electrode EP to which the second power voltage VSS is provided.

The light-receiving element LRD may perform a photoelectric conversion function. As an example, the light-receiving element LRD may generate charges (or a current) based on incident light. The light-receiving element LRD may be implemented as a photo diode.

When the ninth transistor T9 is turned on by the reset signal RST supplied to the reset control line RSTL, the reset voltage VRST may be supplied to the fifth node N5. For example, a voltage of the fifth node N5 may be reset by the reset voltage VRST. After the reset voltage VRST is applied to the fifth node N5, the light-receiving element LRD may perform a photoelectric conversion function.

The voltage of the fifth node N5 may be changed due to the operation of the light-receiving element LRD. The voltage of the fifth node N5 (or charges or a current generated in the light-receiving element LRD) may be changed according to an intensity of light incident on the light-receiving element LRD and a time for which light is incident (or a time for which the light-receiving element LRD is exposed to light).

When the tenth transistor T10 is turned on by the first scan signal GW[i] supplied to the 1i scan line S1i, a detection value (a current and/or a voltage) generated based on the voltage of the fifth node N5 may flow to the k^{th} readout line RXk.

In one or more embodiments, each of the pixel circuit PXC and the sensor circuit SC may include a P-type transistor and/or an N-type transistor. The third transistor T3, the fourth transistor T4, and the ninth transistor T9 may be formed as oxide semiconductor transistors including an oxide semiconductor (or a second type semiconductor). For example, the third transistor T3, the fourth transistor T4, and the ninth transistor T9 may be N-type oxide semiconductor transistors and may include an oxide semiconductor layer as an active layer, but the present disclosure is not limited thereto.

The remaining transistors (for example, the first, second, fifth, sixth, seventh, eighth, and tenth transistors T1, T2, T5, T6, T7, T8, and T10 may be formed as polysilicon transistors including a silicon semiconductor (or a first type semiconductor) and may include a polysilicon semiconductor layer as an active layer. For example, the active layer may be formed through a low-temperature polysilicon process.

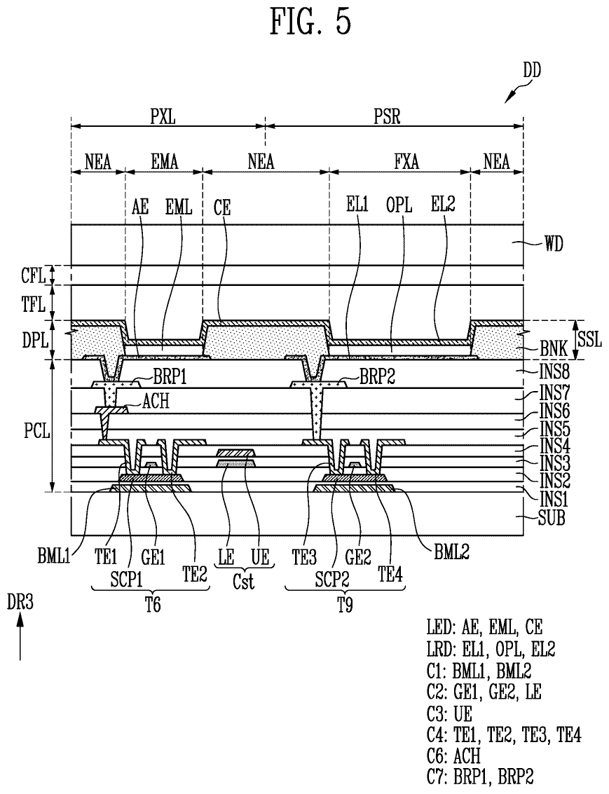

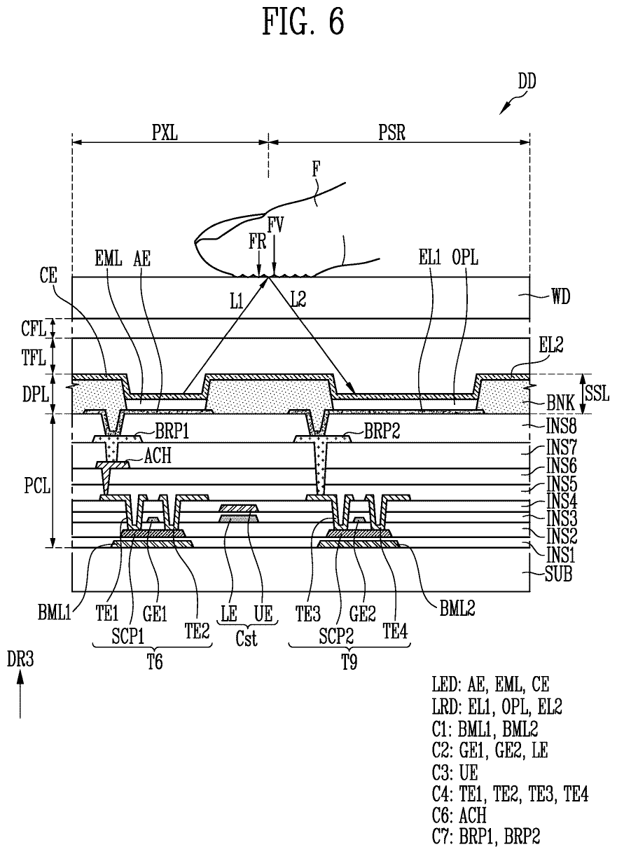

FIG. 5 is a schematic cross-sectional view illustrating one area of the display device of FIG. 1. FIG. 6 is a schematic cross-sectional view illustrating a reflection path of light in the display device of FIG. 5. FIGS. 5 and 6 mainly illustrate a stacked structure (or a cross-sectional structure) of a subpixel PXL including a light-emitting device LED and a light-sensing pixel PSR including a light-receiving device LRD and are cross-sectional views of the sixth transistor T6 among the first to seventh transistors T1, T2, T3, T4, T5, T6, and T7 and the ninth transistor T9 among the eighth to tenth transistors T8, T9, and T10 in FIG. 4.

Referring to FIGS. 5 and 6, a display device DD may include the subpixel PXL and the light-sensing pixel PSR which are located on a substrate SUB.

A pixel circuit layer PCL of the subpixel PXL and a pixel circuit layer PCL of the light-sensing pixel PSR may be located on the substrate SUB. The pixel circuit layer PCL may include first to eighth insulating layers INS1, INS2, INS3, INS4, INS5, INS6, INS7, and INS8 sequentially stacked on the substrate SUB in a third direction DR3.

The first insulating layer INS1 (or a buffer layer) may be entirely located on the substrate SUB. The first insulating layer INS1 may reduce or prevent diffusion of impurities into the sixth transistor T6 and the ninth transistor T9. The first insulating layer INS1 may be an inorganic film including an inorganic material (or substance). The first insulating layer INS1 may include at least one selected from silicon nitride (SiNₓ), silicon oxide (SiOₓ), silicon oxynitride (SiOₓN_{y}), and aluminum oxide (AlOₓ). The first insulating layer INS1 may be provided as a single layer, but may also be provided as a multi-layer including at least a double layer. The first insulating layer INS1 may be omitted according to materials and process conditions of the substrate SUB.

The second insulating layer INS2 (or a first gate-insulating layer) may be entirely located on the first insulating layer INS1. The second insulating layer INS2 may include the same material as the first insulating layer INS1 or may include a material suitable (or selected from) among materials described as constituent materials of the first insulating layer INS1. As an example, the second insulating layer INS2 may be an inorganic film including an inorganic material.

The third insulating layer INS3 (or a second gate-insulating layer) may be entirely located on the second insulating layer INS2. The third insulating layer INS3 may include the same material as the first insulating layer INS1 or may include at least one material suitable (or selected from) among the materials described as the constituent materials of the first insulating layer INS1.

The fourth insulating layer INS4 (or an interlayer insulating layer) may be entirely located on the third insulating layer INS3. The fourth insulating layer INS4 may be an inorganic film including an inorganic material or an organic film including an organic material.

The fifth insulating layer INS5 (or a passivation layer) may be entirely located on the fourth insulating layer INS4. The fifth insulating layer INS5 may be an inorganic film including an inorganic material or an organic film including an organic material.

The sixth insulating layer INS6 (or a first via layer) may be entirely located on the fifth insulating layer INS5. The sixth insulating layer INS6 may be an inorganic film including an inorganic material or an organic film including an organic material. The inorganic film may include at least one selected from silicon oxide (SiOₓ), silicon nitride (SiNₓ), silicon oxynitride (SiOₓN_{y}), and aluminum oxide (AlOₓ). The organic insulating film may include at least one selected from a polyacrylate-based resin, an epoxy-based resin, a phenolic resin, a polyamide-based resin, a polyimide-based resin, an unsaturated polyester-based resin, a poly-phenylene ether-based resin, a poly-phenylene sulfide-based resin, and a benzocyclobutene resin.

The seventh insulating layer INS7 (or a second via layer) may be entirely located on the sixth insulating layer INS6. The seventh insulating layer INS7 may include the same material as the sixth insulating layer INS6 or may include at least one material suitable (or selected from) among materials described as constituent materials of the sixth insulating layer INS6. For example, the seventh insulating layer INS7 may be an organic film including an organic material.

The eighth insulating layer INS8 (or a third via layer) may be entirely located on the seventh insulating layer INS7. The eighth insulating layer INS8 may include the same material as the sixth insulating layer INS6 or may include at least one material suitable (or selected from) among the materials described as the constituent materials of the sixth insulating layer INS6. For example, the eighth insulating layer INS8 may be an organic film including an organic material.

The pixel circuit layer PCL may include one or more conductive layers located between the above-described insulating layers. As an example, the conductive layers may include a first conductive layer C1 provided between the substrate SUB and the first insulating layer INS1, a second conductive layer C2 provided on the second insulating layer INS2, a third conductive layer C3 provided on the third insulating layer INS3, a fourth conductive layer C4 provided on the fourth insulating layer INS4, a fifth conductive layer C5 provided on the fifth insulating layer INS5, a sixth conductive layer C6 provided on the sixth insulating layer INS6, and/or a seventh conductive layer C7 provided on the seventh insulating layer INS7. However, the insulating layers and conductive layers are not limited to the above-described embodiments, and according to embodiments, other insulating layers or other conductive layers in addition to the above-described insulating layers and conductive layers may be located in the pixel circuit layer PCL.

The sixth transistor T6 and the ninth transistor T9 may be part of the pixel circuit layer PCL. The sixth transistor T6 may include a first gate electrode GE1, a first semiconductor pattern SCP1, a first terminal TE1, and a second terminal TE2. The ninth transistor T9 may include a second gate electrode GE2, a second semiconductor pattern SCP2, a third terminal TE3, and a fourth terminal TE4.

The first semiconductor pattern SCP1 and the second semiconductor pattern SCP2 may be located on the first insulating layer INS1. The first semiconductor pattern SCP1 may include a polysilicon semiconductor, and the second semiconductor pattern SCP2 may include an oxide semiconductor, but the present disclosure is not limited thereto. The first semiconductor pattern SCP1 and the second semiconductor pattern SCP2 may each include a channel region, a first contact region connected to one end of the channel region, and a second contact region connected to the other end of the channel region. The first contact region may be a source region, and the second contact region may be a drain region. The second insulating layer INS2 may be located on the first semiconductor pattern SCP1 and the second semiconductor pattern SCP2.

The first gate electrode GE1 and the second gate electrode GE2 may be part of the second conductive layer C2 located on the second insulating layer INS2. The second conductive layer C2 may be formed as a single layer or a multi-layer made of at least one selected from molybdenum (Mo), copper (Cu), chromium (Cr), gold (Au), silver (Ag), titanium (Ti), nickel (Ni), neodymium (Nd), indium (In), tin (Sn), and/or an oxide or alloy thereof. As an example, the second conductive layer C2 may be formed as a multi-layer in which titanium (Ti), copper (Cu), and/or indium tin oxide (ITO) are sequentially or repeatedly stacked. The first gate electrode GE1 may overlap one region of the first semiconductor pattern SCP1. One region of the first semiconductor pattern SCP1 that overlaps the first gate electrode GE1 may be a channel region of the sixth transistor T6. The second gate electrode GE2 may overlap one region of the second semiconductor pattern SCP2. One region of the second semiconductor pattern SCP2 that overlaps the second gate electrode GE2 may be a channel region of the ninth transistor T9.

The third insulating layer INS3 may be located on the first gate electrode GE1 and the second gate electrode GE2.

The first to fourth terminals TE1, TE2, TE3, and TE4 may be part of the fourth conductive layer C4 located on the fourth insulating layer INS4. The fourth conductive layer C4 may be formed as a single layer or a multi-layers made of at least one selected from molybdenum (Mo), copper (Cu), aluminum (Al), chromium (Cr), gold (Au), silver (Ag), titanium (Ti), nickel (Ni), neodymium (Nd), indium (In), tin (Sn), and/or an oxide or alloy thereof.

The first terminal TE1 may be electrically connected to the first contact region of the first semiconductor pattern SCP1 through a contact hole passing through the second to fourth insulating layers INS2, INS3, and INS4. The first terminal TE1 may be electrically connected to an anode AE of the light-emitting element LED.

The second terminal TE2 may be electrically connected to the second contact region of the first semiconductor pattern SCP1 through a contact hole passing through the second to fourth insulating layers INS2, INS3, and INS4.

The third terminal TE3 may be electrically connected to the first contact region of the second semiconductor pattern SCP2 through a contact hole passing through the second to fourth insulating layers INS2, INS3, and INS4. The third terminal TE3 may be electrically connected to a first electrode EL1 of the light-receiving element LRD.

The fourth terminal TE4 may be electrically connected to the second contact region of the second semiconductor pattern SCP2 through a contact hole passing through the second to fourth insulating layers INS2, INS3, and INS4.

The fifth insulating layer INS5 may be located on the first to fourth terminals TE1, TE2, TE3, and TE4.

A first lower metal pattern BML1 and a second lower metal pattern BML2 may be part of the pixel circuit layer PCL. The first lower metal pattern BML1 may be part of the first conductive layer C1 located on the substrate SUB and may overlap the sixth transistor T6. The second lower metal pattern BML2 may be part of the first conductive layer C1 located on the substrate SUB and may overlap the ninth transistor T9. According to embodiments, the first lower metal pattern BML1 may be electrically connected to the sixth transistor T6 to stabilize the channel region of the sixth transistor T6. The second lower metal pattern BML2 may be electrically connected to the ninth transistor T9 to stabilize the channel region of the ninth transistor T9.

A storage capacitor Cst may be part of the pixel circuit layer PCL. The storage capacitor Cst may include a lower electrode LE and an upper electrode UE. The lower electrode LE may be part of the second conductive layer C2. The third insulating layer INS3 may be located on the lower electrode LE.

The upper electrode UE may be located on the third insulating layer INS3. The upper electrode UE may overlap the lower electrode LE with the third insulating layer INS3 interposed therebetween. The upper electrode UE may be part of the third conductive layer C3, but the present disclosure is not limited thereto. The upper electrode UE may form a capacitance by overlapping the lower electrode LE with the third insulating layer INS3 interposed therebetween.

An anode connection portion ACH, a first bridge pattern BRP1, and/or a second bridge pattern BRP2 may be part of the pixel circuit layer PCL.

The anode connection portion ACH may be part of the sixth conductive layer C6 located on the sixth insulating layer INS6. The anode connection portion ACH may be electrically connected to the first terminal TE1 through a contact hole passing through the fifth and sixth insulating layers INS5 and INS6. The anode connection portion ACH may include the same material as the second conductive layer C2 or may include a material suitable (or selected from) among materials described as constituent materials of the second conductive layer C2. The seventh insulating layer INS7 may be located on the anode connection portion ACH.

The first bridge pattern BRP1 and the second bridge pattern BRP2 may be part of the seventh conductive layer C7. The first bridge pattern BRP1 and the second bridge pattern BRP2 may be spaced apart from each other on the seventh insulating layer INS7. The first bridge pattern BRP1 and the second bridge pattern BRP2 may include the same material as the second conductive layer C2 or may include a material suitable (or selected from) among the materials described as the constituent materials of the second conductive layer C2.

The first bridge pattern BRP1 may be electrically connected to the anode connection portion ACH through a contact hole passing through the seventh insulating layer INS7. The second bridge pattern BRP2 may be electrically connected to the third terminal TE3 through a contact hole passing through the fifth to seventh insulating layers INS5, INS6, and INS7. The eighth insulating layer INS8 may be located on the first bridge pattern BRP1 and the second bridge pattern BRP2.

A display element layer DPL may be located on the pixel circuit layer PCL of the subpixel PXL. A sensor layer SSL may be located on the pixel circuit layer PCL of the light-sensing pixel PSR.

The light-emitting element LED and a bank BNK may be part of the display element layer DPL. The light-emitting element (LED) may include an anode AE (or a pixel electrode), a light-emitting layer EML, and/or a cathode CE (or a common electrode). The light-emitting element LED may be electrically connected to the sixth transistor T6. The light-emitting layer EML may include a hole transport layer, an organic material layer (or a light generation layer), and/or an electron transport layer.

A light-receiving element LRD and the bank BNK may be part of the sensor layer SSL. The light-receiving element LRD may be an optical fingerprint sensor. The light-receiving element LRD may recognize a fingerprint by sensing light reflected by a ridge FR of a finger F and a valley FV between the ridges FR. For example, when the finger F of a user touches a window WD, first light L1 emitted from the light-emitting element LED (or the light-emitting layer EML) may be reflected by the ridge FR or the valley FV of the finger F, and reflected second light L2 may reach the light-receiving element LRD (or a light-receiving layer OPL) of the sensor layer SSL. The light-receiving element LRD may recognize a pattern of a finger of a user by distinguishing the second light L2 reflected from the ridges FR of the finger F from the second light L2 reflected from the valley FV of the finger F. The light-receiving element LRD may be electrically connected to the ninth transistor T9. The light-receiving element LRD may include the first electrode EL1 (or a first sensor electrode), the light-receiving layer OPL (or a photoelectric conversion layer), and a second electrode EL2 (or a second sensor electrode).

The anode AE and the first electrode EL1 may be located on the eighth insulating layer INS8. The anode AE and the first electrode EL1 may include a metal layer of silver (Ag), magnesium (Mg), aluminum (Al), platinum (Pt), palladium (Pd), gold (Au), nickel (Ni), neodymium (Nd), iridium (Ir), chromium (Cr), or an alloy thereof, and/or indium tin oxide (ITO), indium zinc oxide (IZO), zinc oxide (ZnO), indium tin zinc oxide (ITZO), or the like. The anode AE may be electrically connected to the first bridge pattern BRP1 through a contact hole passing through the eighth insulating layer INS8. The first electrode EL1 may be electrically connected to the second bridge pattern BRP through a contact hole passing through the eighth insulating layer INS8. The anode AE and the first electrode EL1 may be formed at the same time, but the present disclosure is not necessarily limited thereto.

The bank BNK may be located on the anode AE (e.g., a portion of the anode AE), the first electrode EL1 (e.g., a portion of the first electrode EL1), and/or the eighth insulating layer INS8.

The bank BNK may be a pixel-defining layer that partitions a emission area EMA of the subpixel PXL and a light-receiving area FXA of the light-sensing pixel PSR. The bank BNK may include/define openings corresponding to the emission area EMA and the light-receiving area FXA.

The bank BNK may be an organic film including an organic material (or substance). The organic material may include an acryl resin, an epoxy resin, phenolic resin, a polyamide resin, a polyimide resin, or the like.

According to embodiments, the bank BNK may include a light-absorbing material or may be coated with a light-absorbing material, thereby serving to absorb light introduced from the outside. For example, the bank BNK may include a carbon-based black pigment. However, the present disclosure is not limited thereto, and the bank BNK may include a non-transparent metal material, such as chromium (Cr), molybdenum (Mo), an alloy (MoTi) of molybdenum (Mo) and titanium (Ti), tungsten (W), vanadium (V), niobium (Nb), tantalum (Ta), manganese (Mn), cobalt (Co), or nickel (Ni) which has high light absorptivity.

The light-emitting layer EML may be located on the anode AE. The light-emitting layer EML may include an organic light-emitting layer. According to an organic material included in the light-emitting layer EML, the light-emitting layer EML may emit red light, green light, or blue light, but the present disclosure is not limited thereto.

The light-receiving layer OPL may be located on the first electrode EL1. The light-receiving layer OPL may detect the intensity of light by emitting electrons in response to light in a corresponding wavelength band.

The light-receiving layer OPL may include a low molecular weight organic material (or substance). For example, the light-receiving layer OPL may be made of a phthalocyanine compound at least one metal selected from the group consisting of copper (Cu), iron (Fe), nickel (Ni), cobalt (Co), manganese (Mn), aluminum (AI), palladium (Pd), tin (Sn), indium (In), lead (Pb), titanium (Ti), rubidium (Rb), vanadium (V), gallium (Ga), terbium (Tb), cerium (Ce), lanthanum (La), and/or zinc (Zn).

According to embodiments, the light-receiving layer OPL may be provided as two layers including a layer which includes C60 and a layer which includes a phthalocyanine compound at least one metal selected from the group consisting of copper (Cu), iron (Fe), nickel (Ni), cobalt (Co), manganese (Mn), aluminum (AI), palladium (Pd), tin (Sn), indium (In), lead (Pb), titanium (Ti), rubidium (Rb), vanadium (V), gallium (Ga), terbium (Tb), cerium (Ce), lanthanum (La), and/or zinc (Zn) or may be provided as one mixed layer in which a phthalocyanine compound and C60 are mixed.

In one or more embodiments, the light-receiving layer OPL may determine a light detection band of an optical sensor by controlling the selection of a metal component included in a phthalocyanine compound. For example, a phthalocyanine compound including copper may absorb a visible light wavelength in a band of about 600 nm to about 800 nm, and a phthalocyanine compound including tin (Sn) may absorb a near infrared wavelength in a band of about 800 nm to about 1,000 nm. Therefore, the selection of a metal included in a phthalocyanine compound may be controlled to implement an optical sensor capable of detecting a wavelength in a band desired by a user. For example, the light-receiving element LRD may be formed to selectively absorb a wavelength in a red light band, a wavelength in a green light band, or a wavelength in a blue light band through the light-receiving layer OPL.

The cathode CE may be located on the light-emitting layer EML, and the second electrode EL2 may be located on the light-receiving layer OPL. The cathode CE and the second electrode EL2 may be a common electrode formed integrally in the display area DA. A second power voltage VSS may be supplied to the cathode CE and the second electrode EL2.

The cathode CE and the second electrode EL2 may include a metal layer of Ag, Mg, Al, Pt, Pd, Au, Ni, Nd, Ir, or Cr, and/or a transparent conductive layer of ITO, IZO, ZnO, or ITZO. In one or more embodiments, the cathode CE and the second electrode EL2 may be provided as a multi-layer having at least two layers which includes a thin metal layer, and for example, may be provided as a triple layer of ITO/Ag/ITO.

A thin film encapsulation layer TFL may be entirely formed on the cathode CE and the second electrode EL2.

The thin film encapsulation layer TFL may be provided as a single layer, or may also be provided as a muti-layer. The thin film encapsulation layer TFL may include a plurality of insulating layers covering the light-emitting element LED and the light-receiving element LRD. For example, the thin film encapsulation layer TFL may include at least one inorganic film and at least one organic film. For example, the thin film encapsulation layer TFL may have a structure in which inorganic films and organic films are alternately stacked.

A color filter layer CFL may be located on the thin film encapsulation layer TFL. The color filter layer CFL may include a light-blocking pattern and a color filter. The light-blocking pattern may be located in a non-emission area NEA surrounding the emission area EMA of the subpixel PXL and the light-receiving area FXA of the light-sensing pixel PSR, and the color filter may be located in the emission area EMA and the light-receiving area FXA. The color filter layer CFL may also be used as an anti-reflection layer to block external light reflection. The window WD may be located on the color filter layer CFL.

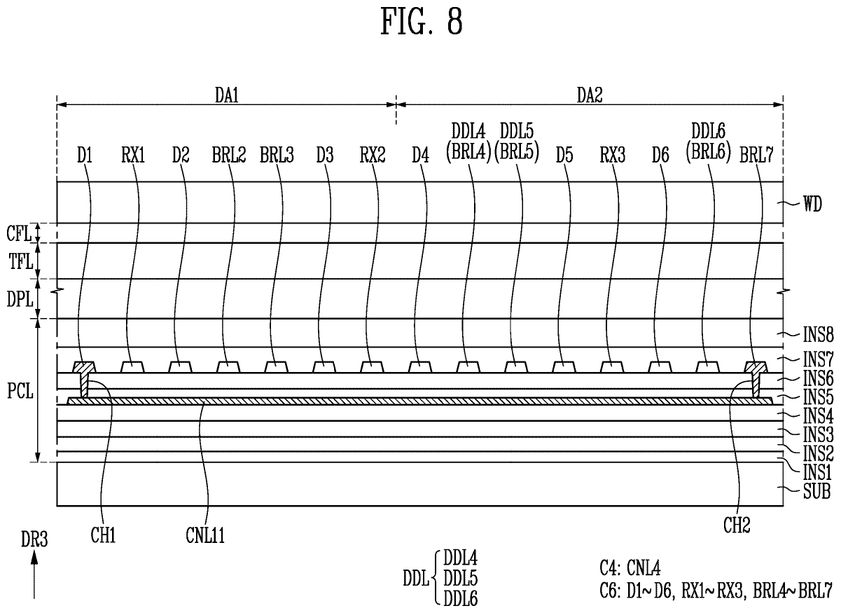

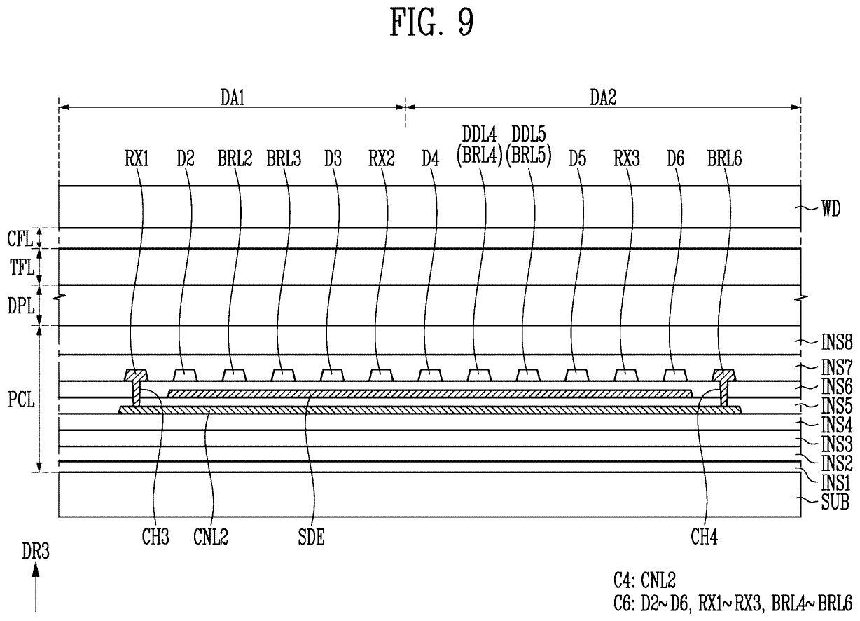

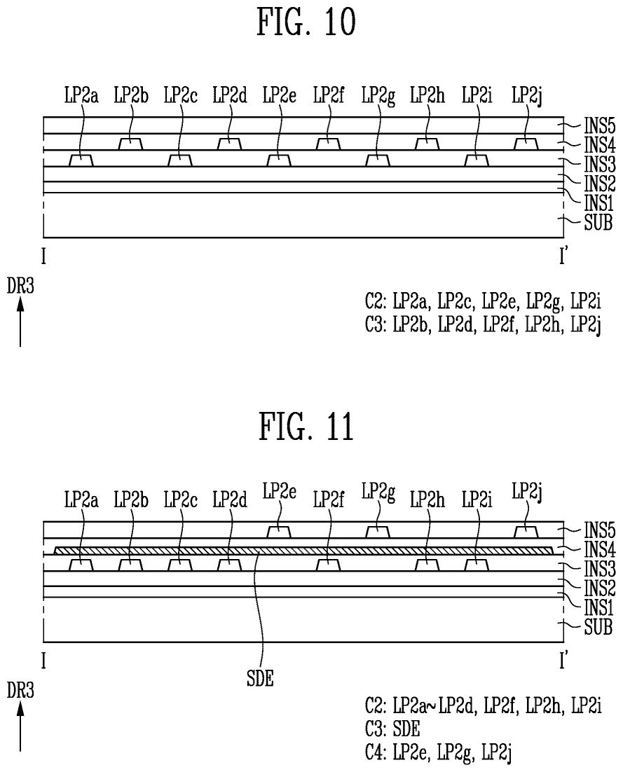

FIG. 7 is a schematic plan view illustrating one area of the display device of FIG. 1. FIG. 7 schematically illustrates a data line, a readout line, a bridge line, a connection line, and a second interconnect. FIG. 8 is a schematic cross-sectional view taken along an eleventh connection line of FIG. 7 which illustrates one or more embodiments of a display device. FIG. 9 is a schematic cross-sectional view taken along a second connection line of FIG. 7 which illustrates one or more embodiments of a display device. FIGS. 10 and 11 are cross-sectional views taken along the line I-I′ of FIG. 7 which illustrates one or more embodiments of a display device.

Referring to FIGS. 1 and 7, second interconnects LP2 (see FIG. 1) positioned in a fan-out area FTA may include a 2a interconnect LP2a, a 2b interconnect LP2b, a 2c interconnect LP2c, a 2d interconnect LP2d, a 2e interconnect LP2e, a 2f interconnect LP2f, a 2g interconnect LP2g, a 2h interconnect LP2h, a 2i interconnect LP2i, and a 2j interconnect LP2j.

Hereinafter, at least one of the 2a to 2j interconnects LP2a to LP2j will be arbitrarily referred to a “second interconnect LP2,” or the 2a to 2j interconnects LP2a to LP2j will be collectively referred to as “second interconnects LP2.”

Signal lines to which various signals are applied may be located in a first area DA1 and a second area DA2.

Data lines D1 to D7 to which data signals are applied may be located in the first area DA1 and the second area DA2. The data lines D1 to D7 may extend from the first area DA1 and the second area DA2 in a second direction DR2, and may be arranged in a first direction DR1 that crosses the second direction DR2.

Readout lines RX1 to RX4 that receive a detection signal from a light-sensing pixel PSR may be located in the first area DA1 and the second area DA2. The readout lines RX1 to RX4 may extend from the first area DA1 and the second area DA2 in the second direction DR2 and may be arranged in the first direction DR1.

For example, each of the readout lines RX1 to RX4 may be located between a respective pair of the data lines D1 to D7. For example, a first readout line RX1 may be located between a first data line D1 and a second data line D2, a second readout line RX2 may be located between a third data line D3 and a fourth data line D4, and a third readout line RX3 may be located between a fifth data line D5 and a sixth data line D6. Although two data lines of the data lines D1 to D7 are illustrated as being located between two adjacent readout lines of the readout lines RX1 to RX4, the present disclosure is not limited thereto. For example, one, three, or four or more data lines of the data lines D1 to D7 may be located between two adjacent readout lines of the data lines RX1 to RX4. The number of readout lines RX1 to RX4 or the number of data lines D1 to D7 is not particularly limited.

In addition, bridge lines BRL may be located in the first area DA1 and the second area DA2. The bridge lines BRL may extend from the first area DA1 and the second area DA2 in the second direction DR2, and may be arranged in the first direction DR1. The bridge lines BRL may respectively correspond to the data lines D1 to D7. The bridge lines BRL are configured to reduce a border (or a dead space), and also may be referred to as a border reduction structure.

As an example, a second bridge line BRL2 and a third bridge line BRL3 may be located between the second data line D2 and the third data line D3, a fourth bridge line BRL4 and a fifth bridge line BRL5 may be located between the fourth data line D4 and the fifth data line D5, and a sixth bridge line BRL6 and a seventh bridge line BRL7 may be located between the sixth data line D6 and a seventh data line D7.

In addition to the data lines D1 to D7, the readout lines RX1 to RX4, and the bridge lines BRL, various signal lines, such as power lines and scan lines, may be located in the first area DA1 and the second area DA2.

As shown in FIGS. 8 and 9, the data lines D1 to D7, the readout lines RX1 to RX4, and the bridge lines BRL may be located on the same layer (for example, a sixth insulating layer INS6), but the present disclosure is not limited thereto.

In the first area DA1 and the second area DA2, subpixels PXL (see FIG. 1) may be located or positioned in areas (for example, pixel areas) partitioned by scan lines (see S1i to S4i of FIG. 4) and data lines (for example, D1 to D7). In the first area DA1 and the second area DA2, light-sensing pixels PSR (see FIG. 1) may be located or positioned in areas partitioned by scan lines (for example, S1i to S4i) and readout lines (for example, RX1 to RX4).

The first data line D1, the first readout line RX1, the second data line D2, the second bridge line BRL2, the third bridge line BRL3, the third data line D3, and the second readout line RX2 may be located in the first area DA1.

The fourth data line D4, the fourth bridge line BRL4, the fifth bridge line BRL5, the fifth data line D5, the third readout line RX3, the sixth data line D6, the sixth bridge line BRL6, the seventh bridge line BRL7, the seventh data line D7, and the fourth readout line RX4 may be located in the second area DA2. Although only seven signal lines are illustrated in FIG. 7 as being located in the first area DA1, this is merely an example for convenience of description. For example, the first area DA1 is an area in which signal lines that are not directly connected to the second interconnects LP2a to LP2j of the fan-out area FTA are located, and the number of signal lines located in the first area DA1 is not particularly limited. For example, dozens of signal lines may be located in the first area DA1.

The signal lines of the second area DA2 may be directly connected to the second interconnects LP2a to LP2j through second contact portions CNT2 (or contact holes). For example, the fourth data line D4 may be connected to the 2a interconnect LP2a, the fourth bridge line BRL4 may be connected to the 2b interconnect LP2b, and the fifth bridge line BRL5 may be connected to the 2c interconnect LP2c. The fifth data line D5 may be connected to the 2d interconnect LP2d, the third readout line RX3 may be connected to the 2e interconnect LP2e, and the sixth data line D6 may be connected to the 2f interconnect LP2f, the sixth bridge line BRL6 may be connected to the 2g interconnect LP2g, the seventh bridge line BRL7 may be connected to the 2h interconnect LP2h, the seventh data line D7 may be connected to the 2i interconnect LP2i, and the fourth readout line RX4 may be connected to the 2j interconnect LP2j.

In embodiments, first and second connection lines CNL1 (e.g., CNL11, CNL12, CNL13) and CNL2 may be located in the first area DA1 and the second area DA2. The first and second connection lines CNL1 and CNL2 may extend in the first direction DR1, and may be arranged in the second direction DR2. The first and second connection lines CNL1 and CNL2 may extend from the first area DA1 to the second area DA2. The first and second connection lines CNL1 and CNL2 may be located on a different layer from the data lines D1 to D7, the readout lines RX1 to RX4, and the bridge lines BRL. As shown in FIGS. 8 and 9, the first and second connection lines CNL1 and CNL2 may be located between a fourth insulating layer INS4 and a fifth insulating layer INS5, or may be part of a fourth conductive layer C4, but the present disclosure is not limited thereto.

The first and second connection lines CNL1 and CNL2 may connect signal lines (for example, data lines and readout lines) positioned in the first area DA1 to corresponding bridge lines BRL positioned in the second area DA2.

The first connection lines CNL1 may connect the data lines D1 to D3 positioned in the first area DA1 to corresponding bridge lines BRL positioned in the second area DA2. For example, an eleventh connection line CNL11 may be connected to the first data line D1 in the first area DA1 through a first contact hole CH1, and may be connected to the seventh bridge line BRL7 in the second area DA2 through a second contact hole CH2. Similar to the eleventh connection line CNL11, a twelfth connection line CNL12 may connect the second data line D2 in the first area DA1 and the fifth bridge line BRL5 in the second area DA2. A thirteenth connection line CNL13 may connect the third data line D3 in the first area DA1 and the fourth bridge line BRL4 in the second area DA2.

The second connection line CNL2 connects a readout line (for example, a first readout line RX1) positioned in the first area DA1 to corresponding bridge lines BRL positioned in the second area DA2. For example, the second connection line CNL2 may be connected to the first readout line RX1 in the first area DA1 through a third contact hole CH3 and may be connected to the sixth bridge line BRL6 in the second area DA2 through a fourth contact hole CH4.

Signal lines positioned in the first area DA1 may be connected to corresponding second interconnects through the first and second connection lines CNL1 and CNL2 and the bridge lines BRL. For example, the first data line D1 may be connected to the 2h interconnect LP2h, the second data line D2 may be connected to the 2c interconnect LP2c, the third data line D3 may be connected to the 2b interconnect LP2b, and the first readout line RX1 may be connected to the second 2g interconnect LP2g.

The second interconnects LP2a to LP2j may not be sequentially connected to the data lines D1 to D7 or the readout lines RX1 to RX4 in the first direction DR1, but may be alternately connected to the data lines D1 to D7 and the readout lines RX1 to RX4 in the first direction DR1. Accordingly, a driver DIC may be alternately connected to the data lines D1 to D7 and the readout lines RX1 to RX4 according to the arrangement order of the second interconnects LP2a to LP2j. For example, based on the first direction DR1, the driver DIC may sequentially output or receive signals for the fourth data line D4, the third data line D3, the second data line D2, the fifth data line D5, the third readout line RX3, the sixth data line D6, the first readout line RX1, the first data line D1, the seventh data line D7, and the fourth readout line RX4.

In one or more embodiments, a shielding electrode SDE (or a shielding layer or a shield layer) may be located between the first and second connection lines CNL1 and CNL2 and signal lines that cross the first and second connection lines CNL1 and CNL2 (or remaining signal lines that are not connected to the first and second connection lines CNL1 and CNL2). A power voltage (or a constant voltage) may be applied to the shielding electrode SDE, but the present disclosure is not limited thereto.

Referring to FIG. 9, for example, the shielding electrode SDE may be located between the second connection line CNL2 and the remaining signal lines (for example, the second data line D2, the sixth data line D6, and the like). In FIG. 9, the shielding electrode SDE is illustrated as being located between the fifth insulating layer INS5 and the sixth insulating layer INS6, or as being part of the fifth conductive layer C5, but the present disclosure is not limited thereto. In addition, in FIG. 9, one shielding electrode SDE is illustrated to generally cover the second connection line CNL2, but the present disclosure is not limited thereto. For example, a plurality of shielding electrodes SDE may be provided to respectively overlap or correspond to the remaining signal lines (for example, the second data line D2, the sixth data line D6, and the like).

In one or more embodiments, dummy lines DDL may be further located in the second area DA2. The dummy lines DDL may be physically separated from the bridge lines BRL connected to the first and second connection lines CNL1 and CNL2. The dummy lines DDL may extend from the bridge lines BRL connected to the first and second connection lines CNL1 and CNL2 in the second direction DR2 (or an extending direction of the bridge lines BRL). For example, referring to FIGS. 7 and 8, a fourth dummy line DDL4 may have a shape separated from the fourth bridge line BRL4 and may extend from the fourth bridge line BRL4 in the second direction DR2. Similar to the fourth dummy line DDL4, a fifth dummy line DDL5 may have a shape separated from the fifth bridge line BRL5, and a sixth dummy line DDL6 may have a shape separated from the sixth bridge line BRL6.

In one or more embodiments, the dummy lines DDL may be in a floating state. For example, the dummy lines DDL may not be directly connected to the data lines D1 to D7, the readout lines RX1 to RX4, the bridge lines BRL, and other lines.

In one or more other embodiments, a power voltage may be applied to the dummy lines DDL. For example, a second power voltage VSS (see FIG. 4) may be applied to the dummy lines DDL, and the dummy lines DDL may be connected to an electrode EP (see FIG. 4). In this case, a drop (or an IR drop) of the second power voltage VSS may be prevented or reduced/alleviated. According to embodiments, the dummy lines DDL may also be the first power line PL1, the second power line PL2, the third power line PL3, the fourth power line PL4, or the fifth power line PL5 shown in FIG. 4.

In embodiments, the second interconnects LP2a to LP2j may be located on a plurality of layers.

For example, referring to FIG. 10, some of the second interconnects LP2a to LP2j may be part of a second conductive layer C2 between a second insulating layer INS2 and a third insulating layer INS3, and others of the second interconnects LP2a to LP2j may be part of a third conductive layer C3 between the third insulating layer INS3 and the fourth insulating layer INS4.

In one or more embodiments, two adjacent second interconnects LP2a to LP2j may be located on different layers. For example, with reference to FIG. 10, the 2a, 2c, 2e, 2g, and 2i interconnects LP2a, LP2c, LP2e, LP2g, and LP2i may be located on the second conductive layer C2 between the second insulating layer INS2 and the third insulating layer INS3, and the 2b, 2d, 2f, 2h, and 2j interconnects LP2b, LP2d, LP2f, LP2h, and LP2j may be located on the third conductive layer C3 between the third insulating layer INS3 and the fourth insulating layer INS4. In this case, an interval between two adjacent second interconnects may be relatively increased, and interference (or noise) between the two adjacent second interconnects may be reduced.

In one or more embodiments, the second interconnects connected to the readout lines RX1 to RX4 among the second interconnects LP2a to LP2j may be located on different layers from the remaining second interconnects. The shielding electrode SDE (or the shielding layer) may be located between the second interconnects connected to the readout lines RX1 to RX4 and the remaining second interconnects. In this case, interference of the remaining interconnects on the second interconnects connected to the readout lines RX1 to RX4 (or a phenomenon in which a detection signal transmitted through the readout lines RX1 to RX4 is affected by a data signal) may be reduced. In other words, coupling capacitors/coupling capacitance that may occur due to overlapping interconnects may be reduced or minimized, and crosstalk may be improved.

Referring to FIGS. 7 and 11, for example, the 2e interconnect LP2e connected to the third readout line RX3, the 2g interconnect LP2g connected to the first readout line RX1, and the 2j interconnect LP2j connected to the fourth readout line RX4 may be located on the fourth conductive layer C4 on the fourth insulating layer INS4, and the remaining second interconnects (for example, the 2a, 2b, 2c, 2d, 2f, 2h, and 2i interconnects LP2a, LP2b, LP2c, LP2d, LP2f, LP2h, and LP2i connected to the data lines D1 to D7) may be located on the second conductive layer C2 between the second insulating layer INS2 and the third insulating layer INS3. The shielding electrode SDE may be located on the third conductive layer C3 between the third insulating layer INS3 and the fourth insulating layer INS4.

According to the above-described embodiments, interconnects (or the second interconnects) connecting signal lines of a display area DA (see FIG. 1) and a pad portion PDP (see FIG. 1) may be intensively located in a corresponding area of the fan-out area FTA. Accordingly, as compared to a case in which the interconnects are entirely located in the fan-out area FTA, an area of the fan-out area FTA (or a dead space) for arranging the interconnects may be reduced.

According to the above-described embodiments, among the interconnects located in the fan-out area FTA, the interconnects connected to the readout lines and the remaining interconnects may be located in different layers with the shielding electrode interposed therebetween. Accordingly, a phenomenon in which a detection signal transmitted through the readout line is influenced by a data signal may be reduced, and the reliability of a display device DD may be improved.

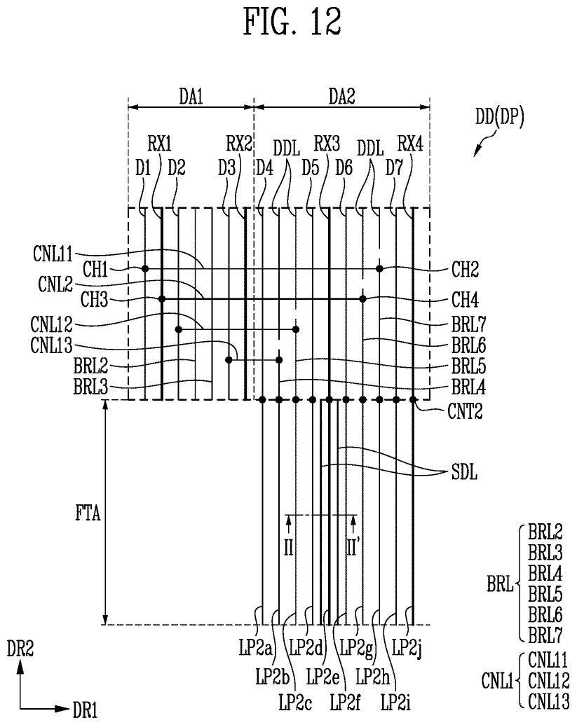

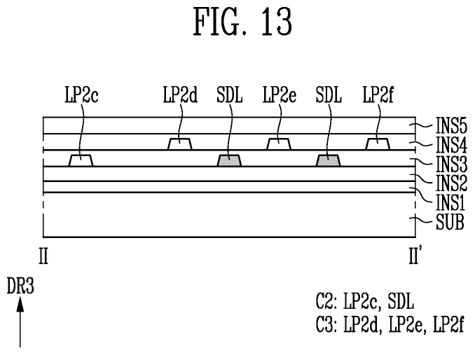

FIG. 12 is a schematic plan view illustrating one area of the display device of FIG. 1. FIG. 13 is a cross-sectional view taken along the line II-II′ of FIG. 12 which illustrates one or more embodiments of a display device.

Referring to FIGS. 7, 12, and 13, a display device DD (or a display panel DP) may further include a shielding line SDL located in a fan-out area FTA.

The shielding line SDL may be located between second interconnects connected to readout lines RX1 to RX4 and remaining second interconnects. The shielding line SDL may extend in a second direction DR2 (or an extending direction of the second interconnect). A power voltage (or a constant voltage) may be applied to the shielding line SDL.

As an example, a 2e interconnect LP2e may be connected to a third readout line RX3. The shielding line SDL may be located between the 2e interconnect LP2e and an adjacent 2d interconnect LP2d. In addition, the shielding line SDL may be located between the 2e interconnect LP2e and a 2f interconnect LP2f adjacent thereto. In this case, a phenomenon in which a detection signal transmitted through the 2e interconnect LP2e is influenced by a data signal transmitted through the 2d interconnect LP2d and/or the 2f interconnect LP2f may be reduced.

In one or more embodiments, the shielding line SDL may be located on a different layer from the second interconnects connected to the readout lines RX1 to RX4. For example, referring to FIG. 13, the second interconnect LP2e may be part of a third conductive layer C3 on a third insulating layer INS3, and the shielding line SDL may be part of a second conductive layer C2 between a second insulating layer INS2 and the third insulating layers INS3. Meanwhile, the 2c interconnect LP2c may be placed on the same layer as the shielding line SDL, and the 2d interconnect LP2d and the 2f interconnect LP2f may be placed on the same layer as the 2e interconnect LP2e.

Meanwhile, in FIG. 12, the shielding line SDL is illustrated as being located only at both sides of the 2e interconnect LP2e, but the present disclosure is not limited thereto. For example, a shielding line SDL may be located at each of both sides of the 2g interconnect LP2g connected to the first readout line RX1, and may also be located at each of both sides of the 2j interconnect LP2j connected to the fourth readout line RX4.

According to the above-described embodiments, among the interconnects located in the fan-out area FTA, the shielding line SDL may be located between the interconnects connected to the readout lines and the remaining interconnects. Accordingly, a phenomenon in which a detection signal transmitted through the readout line is influenced by a data signal may be reduced, and the reliability of the display device DD may be improved.

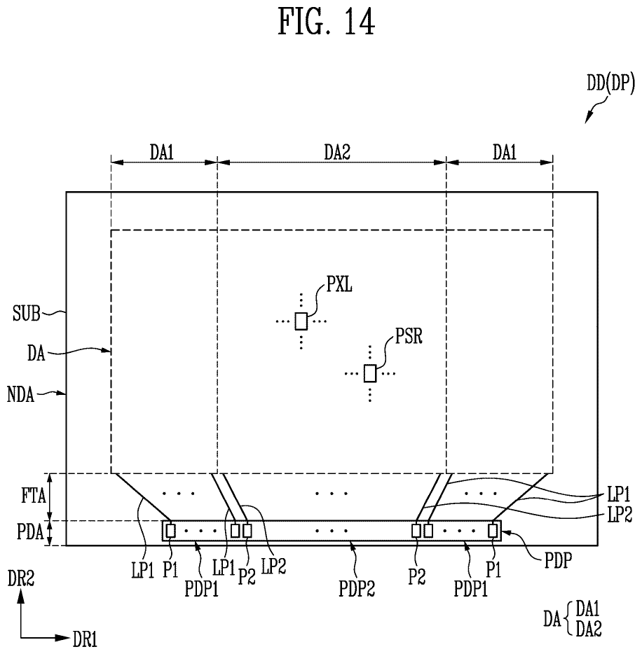

FIG. 14 is a schematic plan view illustrating a display device according to embodiments.

Referring to FIGS. 1, 2, and 14, a display device DD (or a display panel DP) may further include a first interconnect LP1 (or a first wiring). The first interconnect LP1 and a second interconnect LP2 are collectively referred to as a interconnect portion LP.

The first interconnect LP1 of the interconnect portion LP may correspond to a first area DA1 of a display area DA, and the second interconnect LP2 of the interconnect portion LP may correspond to a second area DA2 of the display area DA.

In a fan-out area FTA, the first interconnect LP1 may be positioned at each of both sides of the second interconnect LP2. For example, the second interconnect LP2 may be positioned at a central portion of the fan-out area FTA to correspond to the second area DA2, and the first interconnect LP1 is positioned at an edge of the fan-out area FTA to correspond to the first area DA1. The second interconnect LP2 may be positioned inside the fan-out area FTA, and the first interconnect LP1 may be positioned at a peripheral side of the fan-out area FTA. Accordingly, the first interconnect LP1 and the second interconnect LP2 may be separated in the fan-out area FTA.

The first interconnect LP1 may be located in one area of the fan-out area FTA positioned between the first area DA1 and a pad portion PDP. A plurality of first interconnects LP1 may be provided, and may include fan-out lines electrically connected to subpixels PXL or light-sensing pixels PSR positioned in the first area DA1.

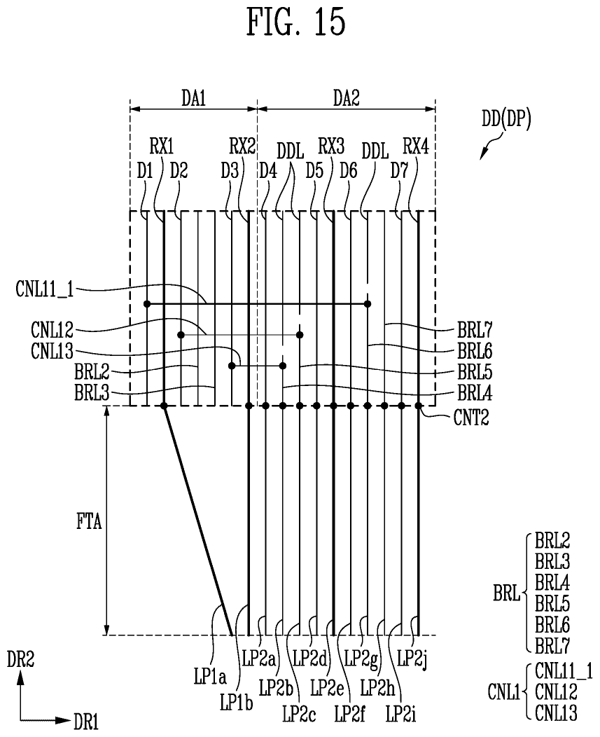

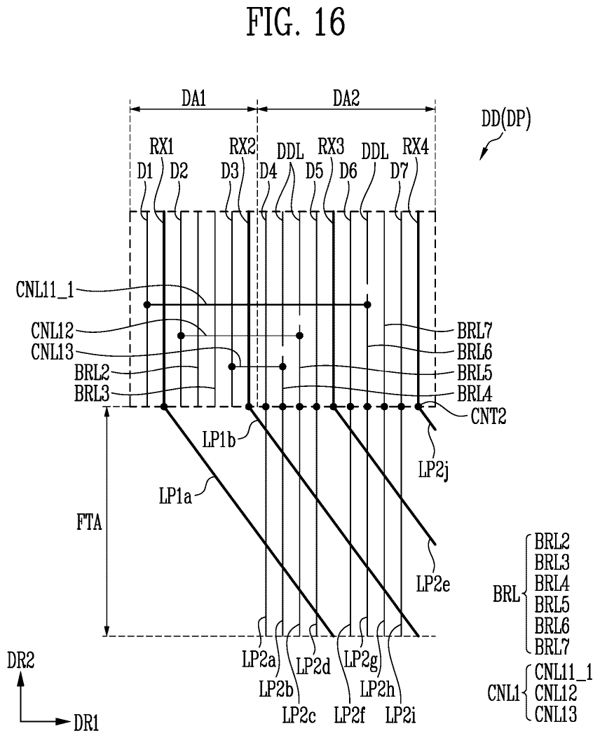

In one or more embodiments, the first interconnects LP1 may include fan-out lines that are electrically connected to data lines connected to the subpixels PXL positioned in the first area DA1 to transmit a data signal to the subpixels PXL. The first interconnect LP1 is not connected to the light-sensing pixels PSR positioned in the first area DA1. In this case, the second interconnects LP2 may include fan-out lines that are electrically connected to readout line connected to the light-sensing pixels PSR positioned in the first area DA1 through connection lines extending from the first area DA1 to the second area DA2. The second interconnect LP2 does not include a fan-out line for the subpixels PXL positioned in the first area DA1. The display device DD according to one or more embodiments will be described below with reference to FIGS. 15 and 16.

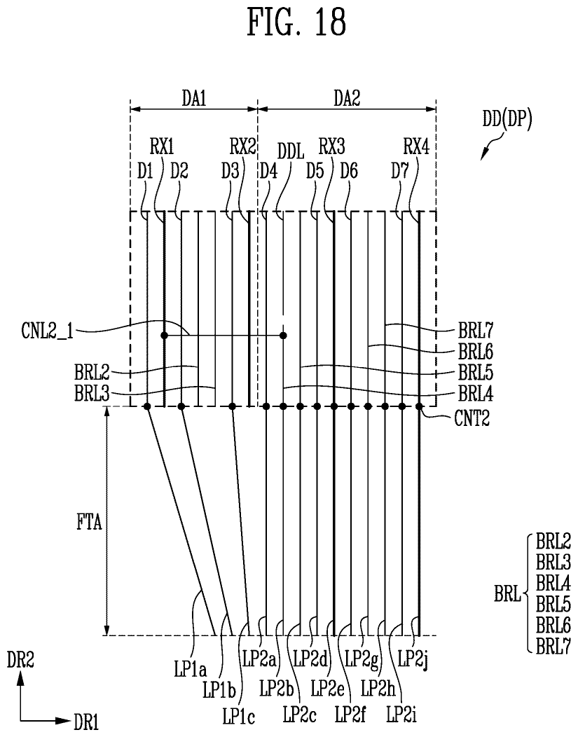

In one or more other embodiments, the first interconnects LP1 may include fan-out lines that are electrically connected to the readout lines connected to the light-sensing pixels PSR positioned in the first area DA1 to transmit an electrical signal (for example, a detection signal) received from the light-sensing pixels PSR to a driver DIC. The first interconnect LP1 is not connected to the subpixels PXL positioned in the first area DA1. In this case, the second interconnects LP2 may include fan-out lines that are electrically connected to data lines connected to the subpixels PXL positioned in the first area DA1 through connection lines extending from the first area DA1 to the second area DA2. The second interconnect LP2 does not include a fan-out line for the light-sensing pixels PSR positioned in the first area DA1. The display device DD according to one or more other embodiments will be described below with reference to FIG. 18.

The pad portion PDP may include a first pad portion PDP1 and a second pad portion PDP2).

In a pad area PDA, the first pad portion PDP1 may be positioned at each of both sides of the second pad portion PDP2. As an example, the second pad portion PDP2 may be positioned at a central portion of the pad area PDA to correspond to the second interconnect LP2, and the first pad portion PDP1 may be positioned at an edge of the pad area PDA to correspond to the first interconnect LP1. The second pad portion PDP2 may be positioned at an inner portion of the pad area PDA, and the first pad portion PDP1 may be positioned at a peripheral side of the pad area PDA, but the present disclosure is not limited thereto.

The first pad portion PDP1 may include a first pad P1 electrically connected to the first interconnect LP1, and the second pad portion PDP2 may include a second pad P2 electrically connected to the second interconnect LP2.

A plurality of first pads P1 may be provided. The first pad P1 may be electrically connected to the subpixels PXL (or the data lines) or the light-sensing pixels PSR (or the readout lines) positioned in the first area DA1 through the corresponding first interconnect LP1).

FIG. 15 is a schematic plan view illustrating one area of the display device of FIG. 14.

Referring to FIGS. 7 and 15, except for 1a and 1b interconnects LP1a and LP1b, a display device DD of FIG. 15 may be substantially the same as or similar to the display device DD of FIG. 7. Therefore, redundant descriptions will not be repeated. The display device DD may omit a second connection line CNL2 (see FIG. 7).

First interconnects LP1 (see FIG. 14) positioned in a fan-out area FTA may include the 1a interconnect LP1a and the 1b interconnect LP1b. At least one of the 1a and 1b interconnects LP1a or LP1b will be arbitrarily referred as a “first interconnect LP1,” or the 1a and 1b interconnects LP1a and LP1b will be collectively referred to as “first interconnects LP1.”

The first interconnects LP1 may be located on the same layer as second interconnects LP2a to LP2j, but the present disclosure is not limited thereto.

Readout lines RX1 and RX2 positioned in a first area DA1 may be directly connected to the first interconnects LP1. For example, a first readout line RX1 may be directly connected to the 1a interconnect LP1a. A second readout line RX2 may be directly connected to the 1b interconnect LP1b.

Data lines D1, D2, and D3 positioned in the first area DA1 may be connected to corresponding second interconnects through first connection lines CNL1. As an example, an eleventh connection line CNL11_1 may connect a first data line D1 and a sixth bridge line BRL6, and the first data line D1 may be connected to a 2g interconnect LP2g through the eleventh connection line CNL11_1 and the sixth bridge line BRL6.

As compared to a case where the first interconnects for all signal lines (for example, readout lines and data lines) of the first area DA1 are located in the fan-out area FTA, the number of first interconnects LP1 may be reduced, and an area of the fan-out area FTA (or a dead space) may be reduced.

Meanwhile, the embodiments described with reference to FIGS. 8 to 13 may be applied to the one or more other embodiments corresponding to FIG. 15.

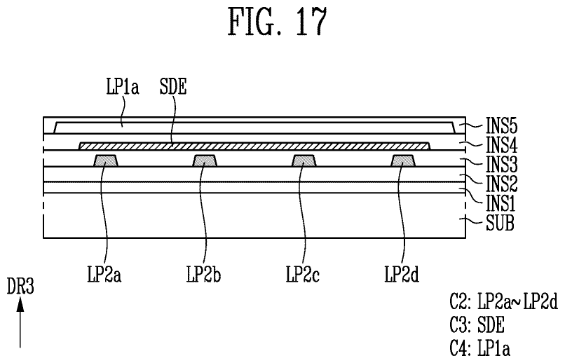

FIG. 16 is a schematic plan view illustrating one area of the display device of FIG. 14. FIG. 17 is a cross-sectional view taken along a 1a interconnect of FIG. 16, which illustrates one or more embodiments of a display device.

Referring to FIGS. 15 and 16, except for the arrangement of 1a and 1b interconnects LP1a and LP1b, a display device DD of FIG. 16 is substantially the same as or similar to the display device DD of FIG. 15. Therefore, redundant descriptions will not be repeated.

First interconnects LP1 may traverse at least some of second interconnects LP2a to LP2j.

As an example, the 1a interconnect LP1a may cross 2a, 2b, 2c, and 2d interconnects LP2a, LP2b, LP2c, and LP2d. One end portion of the 1a interconnect LP1a (for example, a pad connected thereto) may be positioned between the 2d interconnect LP2d and a 2e interconnect LP2e (or pads connected thereto). The 1b interconnect LP1b may cross 2f, 2g, 2h, and 2i interconnects LP2f, LP2g, LP2h, and LP2i other than the 2a, 2b, 2c, and 2d interconnects LP2a, LP2b, LP2c, and LP2d. One end portion of the 1b interconnect LP1b (for example, a pad connected thereto) may be positioned at one side of a 2j interconnect LP2j. Meanwhile, some of the second interconnects connected to readout lines, for example, the 2e and 2j interconnects LP2e and LP2j connected to third and fourth readout lines RX3 and RX4, may be arranged to cross the remaining second interconnects.

Because one end portions of the first interconnects LP1 (or pads connected thereto) are distributed between the second interconnects LP2, an area of the fan-out area FTA (or a dead space) occupied only by the first interconnects LP1 may be reduced. For example, as compared to the one or more other embodiments corresponding to FIG. 15, the area of the fan-out area (FTA) (or the dead space) according to the one or more other embodiments corresponding to FIG. 16 may be reduced.

In one or more embodiments, the first and second interconnects connected to readout lines RX1 to RX4 may be arranged on different layers from the remaining second interconnects. A shielding electrode SDE (or a shielding layer) may be located between the second interconnects connected to the readout lines RX1 to RX4 and the remaining second interconnects. In this case, interference of the remaining interconnects on the second interconnects connected to the readout lines RX1 to RX4 (or a phenomenon in which a detection signal transmitted through the readout lines RX1 to RX4 is affected by a data signal) may be reduced.

Referring to FIG. 17, for example, a 1a interconnect LP1a connected to a first readout line RX1 may be part of a fourth conductive layer C4 on a fourth insulating layer INS4, and the second interconnects (for example, the 2a, 2b, 2c, and 2d interconnects LP2a, LP2b, LP2c, and LP2d) that cross the 1a interconnect LP1a may be part of a second conductive layer C2 between a second insulating layer INS2 and a third insulating layer INS3. The shielding electrode SDE may be located on the third conductive layer C3 between the third insulating layer INS3 and the fourth insulating layer INS4.

According to the above-described embodiments, among the interconnects located in the fan-out area FTA, the interconnects connected to the readout lines and the remaining interconnects may be located in different layers with the shielding electrode interposed therebetween. Accordingly, a phenomenon in which a detection signal transmitted through the readout line is influenced by a data signal may be reduced, and the reliability of the display device DD may be improved.

FIG. 18 is a schematic plan view illustrating one area of the display device of FIG. 14.

Referring to FIGS. 7 and 18, except for first interconnects LP1a to LP1c, a display device DD of FIG. 18 may be substantially the same as or similar to the display device DD of FIG. 7. Therefore, redundant descriptions will not be repeated. The display device DD may not include a first connection line CNL1 (see FIG. 7).

First interconnects LP1 (see FIG. 14) positioned in a fan-out area FTA may include a 1a interconnect LP1a, a 1b interconnect LP1b, and a 1c interconnect LP1c. At least one of the 1a, 1b, and 1c interconnects LP1a, LP1b, or LP1c will be arbitrarily referred to a “first interconnect LP1,” or the 1a, 1b, and 1c interconnects LP1a, LP1b, and LP1c will be collectively referred to as “first interconnects LP1.”

The first interconnects LP1 may be located on the same layer as second interconnects LP2a to LP2j, but the present disclosure is not limited thereto.

Data lines D1 to D3 positioned in a first area DA1 may be directly connected to the first interconnects LP1. For example, a first data line D1 may be directly connected to a 1a interconnect LP1a. A second data line D2 may be directly connected to a 1b interconnect LP1b. A third data line D3 may be directly connected to a 1c interconnect LP1c.

As shown in FIG. 16, readout lines RX1 and RX2 positioned in the first area DA1 may be directly connected to the first interconnects LP1. For example, a first readout line RX1 may be directly connected to the 1a interconnect LP1a. A second readout line RX2 may be directly connected to the 1b interconnect LP1b.

As shown in FIG. 18, the readout line RX1 positioned in the first area DA1 may be connected to the corresponding second interconnect through a second connection line CNL2_1. As an example, the second connection line CNL2_1 may connect the first readout line RX1 and a fourth bridge line BRL4, and the first readout line RX1 may be connected to a 2b interconnect LP2b through the second connection line CNL2_1 and the fourth bridge line BRL4.

As compared to a case in which the first interconnects for all signal lines (for example, readout lines and data lines) of the first area DA1 are located in the fan-out area FTA, the number of first interconnects LP1 may be reduced, and an area of the fan-out area FTA (or a dead space) may be reduced.

Meanwhile, the embodiments described with reference to FIGS. 8 to 13 may be applied to the one or more other embodiments corresponding to FIG. 18.

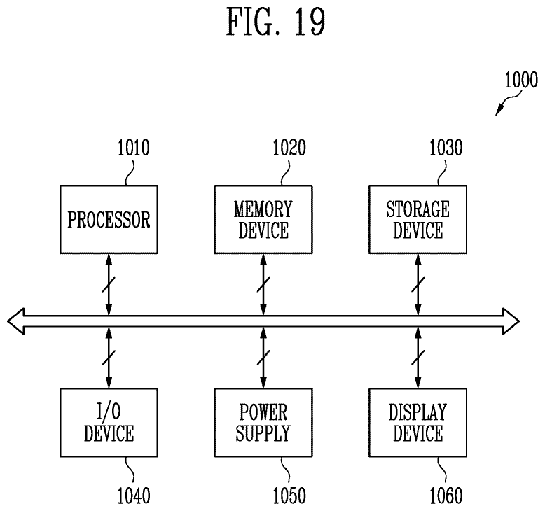

FIG. 19 is a block diagram illustrating an electronic device according to embodiments.

Referring to FIG. 19, an electronic device 1000 may include a processor 1010, a memory device 1020, a storage device 1030, an input/output device 1040, a power supply 1050, and a display device 1060. In this case, the display device 1060 may be the display device DD of FIG. 1. In addition, the electronic device 1000 may further include various ports that may communicate with a video card, a sound card, a memory card, a universal serial bus (USB) device, and the like, or may communicate with other systems. In one or more embodiments, the electronic device 1000 may be implemented as a smartphone or tablet PC. However, this is merely an example, and the electronic device 1000 is not limited thereto. For example, the electronic device 1000 may be implemented as a mobile phone, a video phone, a smart pad, a smart watch, a vehicle navigation device, a computer monitor, a laptop, a head-mounted display device, or the like.

The processor 1010 may perform corresponding calculations or tasks. According to embodiments, the processor 1010 may be a microprocessor, a central processing unit, an application processor, or the like. The processor 1010 may be connected to other components through an address bus, a control bus, and a data bus. According to embodiments, the processor 1010 may also be connected to an expansion bus, such as a peripheral component interconnect (PCI) bus.

The memory device 1020 may store data suitable for the operation of the electronic device 1000. For example, the memory device 1020 may include non-volatile memory devices, such as an erasable programmable read-only memory (EPROM) device, an electrically erasable programmable read-only memory (EEPROM) device, a flash memory device, a phase change random access memory (PRAM) device, a resistance random access memory (RRAM) device, a nano-floating gate memory (NFGM) device, a polymer random access memory (PoRAM) device, a magnetic random access memory (MRAM) device, and a ferroelectric random access memory (FRAM) device, and/or volatile memory devices, such as a dynamic random access memory (DRAM) device, a static random access memory (SRAM) device, and a mobile DRAM device.

The storage device 1030 may include a solid state drive (SSD), a hard disk drive (HDD), a CD-ROM, and the like.

The input/output device 1040 may include an input means, such as a keyboard, a keypad, a touchpad, a touch screen, or a mouse, and an output means, such as a speaker or a printer. According to embodiments, the display device 1060 may be included in the input/output device 1040.

The power supply 1050 (or a power supply device) may supply power suitable for the operation of the electronic device 1000. For example, the power supply 1050 may be a power management integrated circuit (PMIC).

The display device 1060 may display an image corresponding to visual information of the electronic device 1000. In this case, the display device 1060 may be an organic light-emitting display device or a quantum dot light-emitting display device, but is not limited thereto. The display device 1060 may be connected to other components through the buses or other communication links.

According to the above-described embodiments, interconnects connecting signal lines of a display area and a pad portion may be located intensively in a corresponding area (or a fan-out area) of a non-display area. Accordingly, as compared to a case in which interconnects are entirely located in a non-display area, an area of the non-display area (or a dead space) for arranging the interconnects may be reduced.

According to the above-described embodiments, among interconnects located in a non-display area (or a fan-out area), an interconnect connected to a readout line and the remaining interconnects may be located on different layers with a shielding electrode interposed therebetween. Accordingly, a phenomenon in which a detection signal transmitted through a readout line is affected by a data signal may be reduced. In addition, the reliability of a display device may be improved by reducing or minimizing a coupling capacitance that may occur due to overlapping interconnects and improving crosstalk.

The aspects according to embodiments are not limited to the contents described above, and more various effects are included in the present specification.

It will be understood by those skilled in the art that the present disclosure may be embodied in various other forms without departing from the spirit or essential characteristics thereof. Therefore, the disclosed methods should be considered in an illustrative rather than a restrictive sense. The scope of the present disclosure is defined by the appended claims, with functional equivalents thereof to be included therein, rather than by the foregoing description, and all differences within the scope of equivalents thereof should be construed as being included in the present disclosure.

What is claimed is:

1. A display device comprising:
a substrate having a display area comprising a first area and a second area, and a non-display area;
first signal lines comprising data lines connected to pixels, and readout lines connected to sensor pixels, in the first area and in the second area;
second signal lines between the first signal lines in the first area and in the second area; and
connection lines in the display area, and connecting at least some of the first signal lines in the first area to corresponding ones of the second signal lines in the second area.

2. The display device of claim 1, wherein the first signal lines and the second signal lines extend in a second direction, and are arranged along a first direction crossing the second direction, and
wherein the first area and the second area are separated in the first direction.

3. The display device of claim 1, wherein the data lines and the readout lines in the first area are respectively connected to corresponding ones of the connection lines.

4. The display device of claim 3, further comprising third signal lines connected to pads in the non-display area, directly connected to some of the first signal lines in the second area, and connected to others of the first signal lines in the first area through the connection lines.

5. The display device of claim 4, further comprising a driver connected to the first signal lines and the second signal lines through the third signal lines, and alternately connected to the data lines and the readout lines according to an arrangement order of the third signal lines.

6. The display device of claim 3, wherein the data lines comprise a first data line, a second data line, a third data line, a fourth data line, and a fifth data line sequentially located along a first direction in plan view,
wherein the second signal lines comprise:
a second bridge line and a third bridge line between the second data line and the third data line; and
a fourth bridge line and a fifth bridge line between the fourth data line and the fifth data line,
wherein the second data line in the first area is connected to the fifth bridge line in the second area through a first connection line, and
wherein the third data line in the first area is connected to the fourth bridge line in the second area through a second connection line.

7. The display device of claim 6, wherein the readout lines comprise:
a first readout line between the first data line and the second data line; and
a second readout line between the third data line and the fourth data line, and
wherein the first readout line in the first area is connected to a sixth bridge line between a sixth data line and a seventh data line in the second area through a third connection line.

8. The display device of claim 3, further comprising dummy lines extending from the second signal lines connected to the connection lines in an extending direction of the second signal lines, and physically separated from the second signal lines.

9. The display device of claim 8, wherein the dummy lines are floating, and are physically separated from the first signal lines.

10. The display device of claim 8, wherein the dummy lines are configured to receive a power voltage.

11. The display device of claim 1, further comprising:
third signal lines in the non-display area, and connecting the first signal lines and the second signal lines with pads; and
a shielding layer between one of the third signal lines connected to the readout lines and others of the first, second, and third signal lines,
wherein the one of the third signal lines is at a different layer from the others of the first, second, and third signal lines with the shielding layer therebetween.

12. The display device of claim 1, further comprising:
third signal lines in the non-display area, and connecting the first signal lines and the second signal lines with pads; and
shielding lines between ones of the third signal lines connected to the readout lines and others of the first, second, and third signal lines.

13. The display device of claim 12, wherein at least some of the others of the first, second, and third signal lines and the ones of the third signal lines are at a same layer, and
wherein the shielding lines are at a different layer from the ones of the third signal lines.

14. The display device of claim 1, wherein, in the first area, the data lines are connected to the connection lines, and
wherein the readout lines in the first area are not connected to the connection lines.

15. The display device of claim 14, further comprising third signal lines in the non-display area and connected to pads,
wherein the readout lines in the first area and the first signal lines in the second area are directly connected to the third signal lines, and
wherein the data lines in the first area are connected to the third signal lines through the connection lines.

16. The display device of claim 15, further comprising a shielding layer between one of the third signal lines connected to the readout lines and others of the first, second, an third signal lines,
wherein the one of the third signal lines is at a different layer from the others of the first, second, and third signal lines with the shielding layer therebetween.

17. The display device of claim 1, wherein the readout lines in the first area are connected to the connection lines, and
wherein the data lines in the first area are not connected to the connection lines.

18. The display device of claim 17, further comprising third signal lines in the non-display area and connected to pads,
wherein the data lines in the first area and the first signal lines in the second area are directly connected to the third signal lines, and
wherein the readout lines in the first area are connected to the third signal lines through the connection lines.

19. The display device of claim 1, wherein the pixels comprise a light-emitting element, and
wherein the sensor pixels comprise a light-receiving element at a same layer as the light-emitting element.

20. An electronic device comprising:
a processor configured to provide input image data;
a display device configured to display an image based on the input image data; and
a power supply device configured to supply power to the display device,
wherein the display device comprises:
a substrate having a display area comprising a first area and a second area, and a non-display area;
first signal lines in the first area and in the second area, and comprising data lines connected to pixels, and readout lines connected to sensor pixels;
second signal lines between the first signal lines in the first area and the second area; and
connection lines in the display area, and configured to connect at least some of the first signal lines in the first area to corresponding ones of the second signal lines in the second area.
